(19) United States
(12) Patent Application Publication
(10) Pub. No.: US 2014/0103316 A1
(43) Pub. Date: Apr. 17, 2014

(54) ORGANOMETALLIC COMPLEX AND ORGANIC LIGHT-EMITTING DEVICE INCLUDING THE SAME

(71) Applicants: Industry-Academic Cooperation Foundation Gyeongsang National University, Jinju (KR); Samsung Display Co., Ltd., Yongin-City (KR)

(72) Inventors: Mi-Kyung Kim, Yongin-City (KR); Kwan-Hee Lee, Yongin-City (KR); Moon-Jae Lee, Yongin-City (KR); Chang-Woong Chu, Yongin-City (KR); Se-Hun Kim, Yongin-City (KR); Yun-Hi Kim, Jinju (KR); Soon-Ki Kwon, Jinju (KR); Chul-Young Kim, Jinju (KR)

(21) Appl. No.: 14/053,702

(22) Filed: Oct. 15, 2013

(30) Foreign Application Priority Data
Oct. 12, 2012 (KR) 10-2012-0113826
Sep. 25, 2013 (KR) 10-2013-0114042

(51) Int. Cl. H01L 51/00

(52) U.S. Cl. CPC H01L 51/0085
USPC 257/40; 546/2

(57) ABSTRACT

An organometallic complex and an organic light-emitting device (OLED) including the same are described. In exemplary embodiments, the subject OLED devices may comprise an alkyl derivative of a tris(2-phenylpyridine)iridium complex paired with a carbazole-based host in an emission layer and emit green phosphorescent light.

### CLAIM OF PRIORITY

This application makes reference to, incorporates the same herein, and claims all benefits accruing under 35 U.S.C. §119 from an application earlier filed on 12 Oct. 2012 and there duly assigned Serial No. 10-2012-0113826 and an application filed on 25 Sep. 2013 and there duly assigned Serial No. 10-2013-0114042 in the Korean Intellectual Property Office.

### BACKGROUND OF THE INVENTION

1. Field of the Invention

The present invention relates to an organometallic complex and an organic light-emitting device including the same.

2. Description of the Related Art

An organic light-emitting device (OLED), which is a self-emitting device, has advantages such as wide viewing angles, excellent contrast, quick response, high brightness, excellent driving voltage characteristics and multicolored images.

A typical OLED has a structure including an anode formed on top of a substrate and a hole transport layer (HTL), an emission layer (EML), an electron transport layer (ETL), and a cathode, which are sequentially stacked on top of the anode. In this regard, the HTL, the EML, the ETL are organic thin films formed of organic compounds.

An operating principle of an OLED having the above-described structure is as follows.

When a voltage is applied between the anode and the cathode, holes injected from the anode move to the EML via the HTL, and electrons injected from the cathode move to the EML via ETL. Carriers such as the holes and the electrons recombine in the EML regions to generate excitons. When the excitons drop from an excited state to a ground state, light is emitted.

### SUMMARY OF THE INVENTION

The present invention provides a novel organometallic complex.

According to an aspect of the present invention, there is provided an organometallic complex represented by Formula 1:

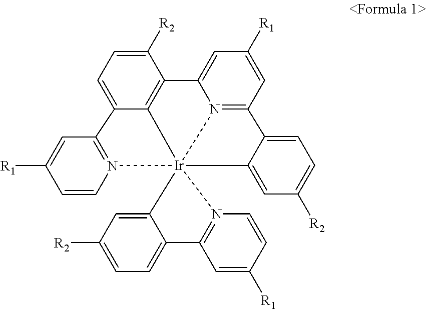

R₁ in Formula 1 is a hydrogen atom or a C₁-C₁₀ alkyl group; and

R₂ in Formula 1 is a C₁-C₁₀ alkyl group.

According to another aspect of the present invention, there is provided an OLED including a substrate, a first electrode, a second electrode disposed opposite to the first electrode, and an organic layer disposed between the first electrode and the second electrode, and the organic layer includes more than one species of the organometallic complexes according to Formula 1 above.

### BRIEF DESCRIPTION OF THE DRAWINGS

The above and other features and advantages of the present invention will be made more apparent by describing in detail exemplary embodiments thereof with reference to the attached drawings in which:

FIG. 1 is a view schematically illustrating a structure of an organic light-emitting device, according to an embodiment of the present invention;

FIG. 2 is a graphical view illustrating ultraviolet (UV) absorption spectrum and photoluminescent (PL) spectrum of Complex 1, which was prepared according to Synthesis Example 1;

FIG. 3 is a graphical view illustrating UV absorption spectrum and PL spectrum of Complex 2, which was prepared according to Synthesis Example 2;

FIG. 4 is a graphical view illustrating thermogravimetric analysis (TGA) data of Complex 1, which was prepared according to Synthesis Example 1;

FIG. 5 is a graphical view illustrating differential scanning calorimetry (DSC) data of Complex 1, which was prepared according to Synthesis Example 1;

FIG. 6 is a graphical view illustrating thermogravimetric analysis (TGA) data of Complex 2, which was prepared according to Synthesis Example 2;

FIG. 7 is a graphical view illustrating differential scanning calorimetry (DSC) data of Complex 2, which was prepared according to Synthesis Example 2;

FIG. 8 is a graphical view illustrating thermogravimetric analysis (TGA) data of Complex 3, which was prepared according to Synthesis Example 3;

FIG. 9 is a graphical view illustrating differential scanning calorimetry (DSC) data of Complex 3, which was prepared according to Synthesis Example 3;

FIG. 10 is a graphical view illustrating thermogravimetric analysis (TGA) data of Complex 5, which was prepared according to Synthesis Example 5;

FIG. 11 is a graphical view illustrating differential scanning calorimetry (DSC) data of Complex 5, which was prepared according to Synthesis Example 5;

FIG. 12 is a graphical view illustrating cyclic voltammetric (CV) data of Complex 1, which was prepared according to Synthesis Example 1;

FIG. 13 is a graphical view illustrating CV data of Complex 2, which was prepared according to Synthesis Example 2;

FIG. 14 is a graphical view illustrating cyclic voltammetric (CV) data of Complex 3, which was prepared according to Synthesis Example 3;

FIG. 15 is a graphical view illustrating CV data of Complex 5, which was prepared according to Synthesis Example 5;

FIG. 16 is a graphical view illustrating electroluminescent (EL) spectrum of an organic light-emitting device, which was prepared according to Example 1;

FIG. 17 is graphical views illustrating voltage-current density and voltage-luminescence of organic light-emitting devices that were prepared according to Examples from 1 to 5;

FIG. 18 is a graphical view illustrating voltage-current density-quantum efficiency (EQE) of organic light-emitting devices that were prepared according to Examples from 1 to 5;

FIG. 19 is graphical views illustrating electroluminescent (EL) spectrum of organic light-emitting devices, which were prepared according to Examples 6 and 7;

FIG. 20 is graphical views illustrating voltage-current density of organic light-emitting devices that were prepared according to Examples 6 and 7.

### DETAILED DESCRIPTION OF THE INVENTION

As used herein, the term “and/or” includes any and all combinations of one or more of the associated listed items. Expressions such as “at least one of,” when preceding a list of elements, modify the entire list of elements and do not modify the individual elements of the list.

According to an aspect of the present invention, there is provided an organometallic complex represented by Formula 1:

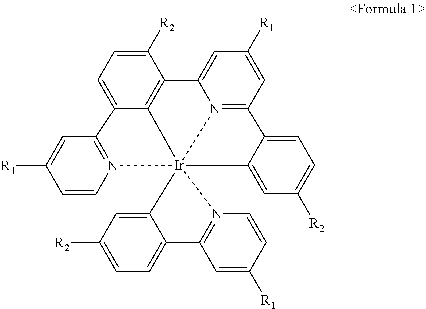

In Formula 1 above, R₁ is a hydrogen atom or a C₁-C₁₀ alkyl group; and R₂ is a C₁-C₁₀ alkyl group.

For example, R₁ and R₂ may be each independently one of a methyl group, an ethyl group, a propyl group, an n-butyl group, an isobutyl group, a sec-butyl group, a tert-butyl group, an n-pentyl group, an isopentyl group, a sec-pentyl group, a tert-pentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonenyl group, an isononenyl group, a sec-nonenyl group, a tert-nonenyl group, an n-decanyl group, an isodecanyl group, a sec-decanyl group, and a tert-decanyl group, but are not limited thereto.

According to an embodiment of the present invention, R₁ and R₂ in Formula 1 may be each independently either an ethyl group or a tert-butyl group.

In Formula 1, R₁ and R₂ may be identical or different. In photoluminescent (PL) spectra of the organometallic complex represented by Formula 1, an emission peak may have a maximum emission wavelength in a range of from about 500 nm to about 530 nm and may have a full width at half maximum (FWHM) in a range of from about 55 nm to about 64 nm (e.g., in a range of from about 55 nm to about 62 nm). PL spectrum of the organometallic complex represented by Formula 1 has the above-described maximum emission wavelength and FWHM; therefore, the organometallic complex may emit green phosphorescence with high color purity; emission is not shifted to red light regions.

According to another embodiment of the present invention, the organometallic complex may be one of the Complexes 1 to 5 below, but is not limited thereto:

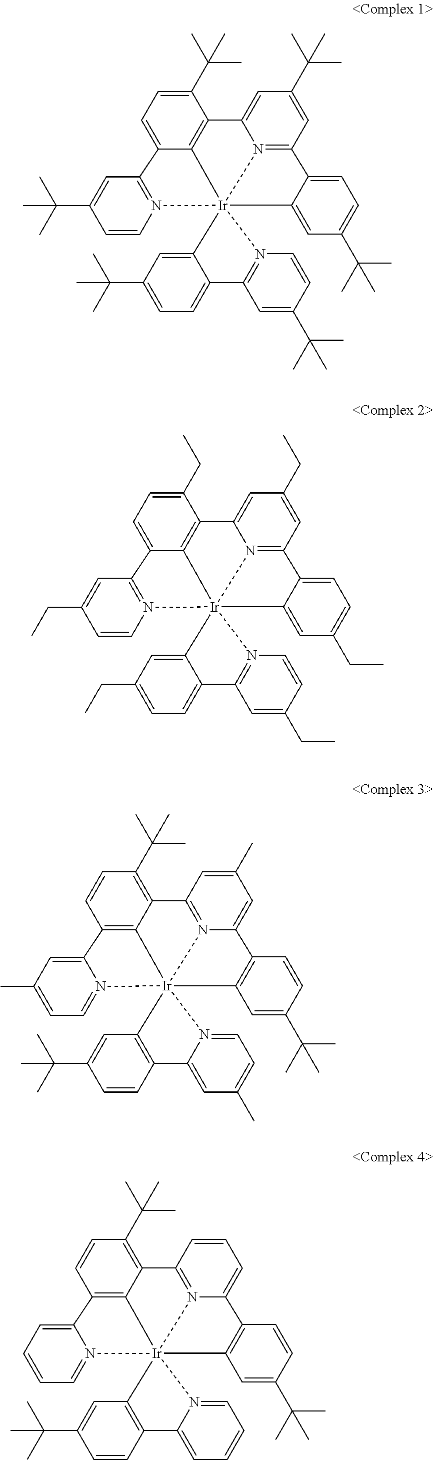

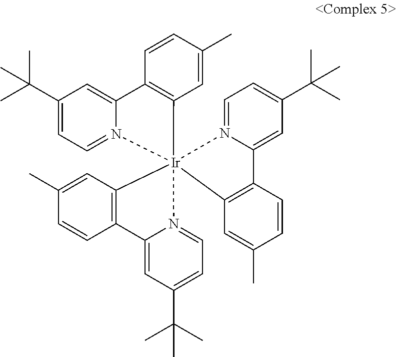

In Formula 1, R₁ and R₂ may be a hydrogen atom or a C₁-C₁₀ alkyl group. Thereby, the organometallic complex represented by Formula 1 may provide green phosphorescent light emission with high color purity, and this is evident from the PL spectrum. The FWHM of the emission peak in the PL spectrum is reduced by alkyl substitution of R₁ and R₂ in Formula 1, and a shift to the red light regions may be avoided by such alkyl substitution as well. When R₁ and R₂ in Formula 1 are electron withdrawing groups such as halogen atoms or aromatic groups such as phenyl groups, the organometallic complex may emit blue light.

In the organometallic complex of Formula 1, R₁ is substituted in the para-position to the nitrogen of the pyridine ring, and, when R₁ is an alkyl group, it may provide an electron donation effect. In addition, in the organometallic complex represented by Formula 1, R₂ is substituted in the meta-position to the Ir-bound carbon of the benzene ring, so the organometallic complex may maintain its structure stably despite exposure to high temperatures such as those that may obtain during a deposition process. Therefore, an organometallic complex of Formula 1 may provide excellent film formation characteristics.

The organometallic complex of Formula 1 may be synthesized by using known organic synthesis methods. A synthesis method for preparing this organometallic complex may be easily understood by those of ordinary skill in the art with reference to the Examples described later.

One or more species of the organometallic complexes of Formula 1 may be used between a pair of electrodes of an organic light-emitting device (OLED). For example, at least one species of the organometallic complexes of Formula 1 may be used in an emission layer (EML).

According to another embodiment of the preset invention, there is provided an OLED including a first electrode, a second electrode disposed opposite to the first electrode, and an organic layer disposed between the first electrode and the second electrode, the organic layer including at least one species of organometallic complex according to Formula 1.

The term “(organic layer) including more than one species of the organometallic complexes” as used herein means “(organic layer) including one species of organometallic complex according to Formula 1, or at least two different species of organometallic complexes according to Formula 1.”

For example, the organic layer may include Complex 1 only as the organometallic complex. Herein, Complex 1 may be included in the EML of the OLED. Meanwhile, the organic layer may include Complex 1 and Complex 2 as the organometallic complex. Herein, Complex 1 and Complex 2 may be included in an identical layer (e.g., present in the EML).

The organic layer may include at least one layer selected from among a hole injection layer, a hole transport layer, a functional layer having both hole injection and hole transport capabilities (hereinafter, “H-functional layer”), a buffer layer, an electron blocking layer, a light emission layer, a hole blocking layer, an electron transport layer, an electron injection layer, and a functional layer having both electron injection and electron transport capabilities (hereinafter, E-functional layer”).

The term “organic layer” as used herein refers to a single layer and/or a multilayer disposed between the first and second electrodes of the OLED.

The organic layer may include an emission layer, and the emission layer may include at least one species of the organometallic complex.

The organometallic complex included in the emission layer may serve as a phosphorescent dopant, and the emission layer may further include a host. Kinds of the host will be described later.

As described above, the OLED including the organometallic complex may emit green light, for example, green phosphorescent light.

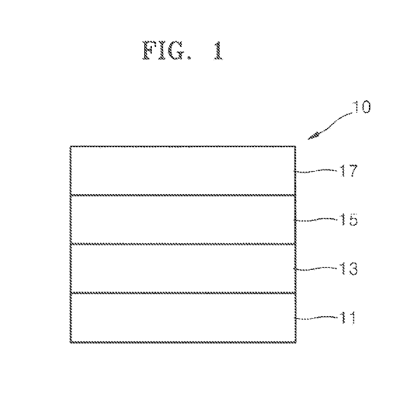

FIG. 1 is a schematic sectional view of the OLED 10 according to an embodiment of the present invention. Hereinafter, a structure for and a method of manufacturing the OLED, according to an embodiment of the present invention with reference to FIG. 1, will be described.

The substrate 11 may, without limitation, be a glass substrate or a transparent plastic substrate with excellent mechanical strength, thermal stability, transparency, surface smoothness, ease of handling, and water resistance.

The first electrode 13 may be formed by providing first electrode-forming materials on top of the substrate via a deposition method, a sputtering method, or the like. When the first electrode 13 is an anode, the first electrode-forming materials to facilitate hole injection may be selected from among materials having a high work function. The first electrode 13 may be a reflective electrode or a transmission electrode. Examples of the first electrode-forming materials are indium tin oxide (ITO), indium zinc oxide (IZO), tin oxide (SnO₂), zinc oxide (ZnO), and the like, which are transparent and highly conductive. Meanwhile, the first electrode 13 may be formed as a reflective electrode from one of magnesium (Mg), aluminum (Al), aluminum-lithium (Al—Li), calcium (Ca), magnesium-indium (Mg—In), magnesium-silver (Mg—Ag), and the like.

The first electrode 13 may have a single layer structure or a multilayer structure of two or more kinds of layers. For example, the first electrode 13 may have a three-layer structure of ITO/Ag/ITO, but is not limited thereto.

The organic layer 15 may be disposed on top of the first electrode 13.

The organic layer 15 may include a hole injection layer, a hole transport layer, a buffer layer, an emission layer, an electron transport layer, and an electron injection layer.

A hole injection layer (HIL) may be formed on top of the first electrode 13 by vacuum deposition, spin coating, casting, Langmuir Blodgett (LB) deposition, or the like.

When the HIL is formed using vacuum deposition, the vacuum deposition conditions may vary according to the compound that is used as a material to form the HIL and the desired structure and thermal properties of the HIL to be formed. For example, vacuum deposition may be performed at a temperature of about 100° C. to about 500° C., a pressure of about 10⁻⁸ torr to about 10⁻³ torr, and a deposition rate of about 0.01 Å/sec to about 100 Å/sec. However, the deposition conditions are not limited thereto.

When the HIL is formed using spin coating, the coating conditions may vary according to the compound that is used as a material to form the HIL and the desired structure and thermal properties of the HIL to be formed. For example, the coating rate may be in a range of about 2000 rpm to about 5000 rpm, and a temperature at which heat treatment is performed to remove a solvent after coating may be in a range of about 80° C. to about 200° C. However, the coating conditions are not limited thereto.

Various materials may be used to form the HIL. Examples of useful HIL materials are, but are not limited to, a phthalocyanine compound such as N,N′-diphenyl-N,N′-bis-[4-(phenyl-m-tolyl-amino)-phenyl]-biphenyl-4,4′-diamine (DNTPD), copper phthalocyanine, 4,4′,4″-tris (3-methylphenylphenylamino)triphenylamine (m-MTDATA), N,N′-di(1-naphthyl)-N,N′-diphenylbenzidine (NPB), TDATA, 2-TNATA, polyaniline/dodecylbenzenesulfonic acid (Pani/DBSA), poly(3,4-ethylenedioxythiophene)/poly(4-styrenesulfonate (PEDOT/PSS), polyaniline/Ccmphor sulfonic acid (Pani/CSA), or polyaniline/poly(4-styrenesulfonate) (PANI/PSS).

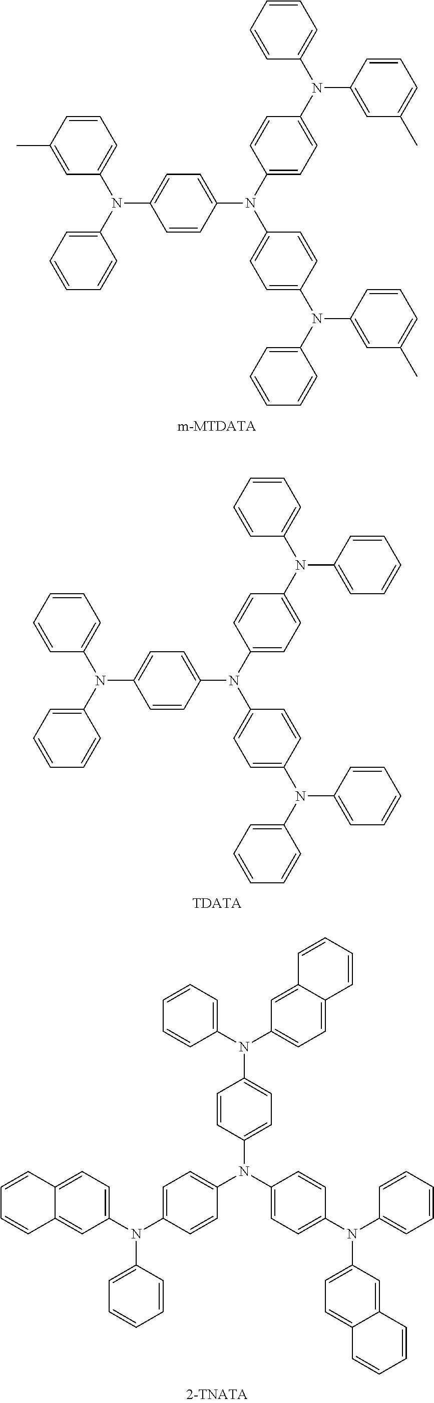

A thickness of the HIL may be from about 100 Å to about 10000 Å, and in some embodiments, may be from about 100 Å to about 1000 Å. When the thickness of the HIL is within these ranges, the HIL may have satisfactory hole injecting abilities without imparting a driving voltage to the OLED device that is substantially too high.

Then, a hole transport layer (HTL) may be formed on top of the HIL using one of vacuum deposition, spin coating, casting, Langumuir-Blodgett (LB) deposition, and the like. When the HTL is formed using one of vacuum deposition and spin coating, the conditions for deposition and coating may vary according to the material that is used to form the HTL, but the conditions may be similar to those for the formation of the HIL.

Examples of known hole transporting materials are, but are not limited to, carbazole derivatives such as N-phenylcarbazole and polyvinylcarbazole, N,N′-bis(3-methyphenyl)-N,N-diphenyl-[1,1-biphenyl]-4,4′-diamine (TPD), 4,4′,4″-tris (N-carbazolyl)triphenylamine(TCTA), and N,N′-di(1-naphthyl)-N,N′-diphenylbenzidine (NPB), but are not limited thereto.

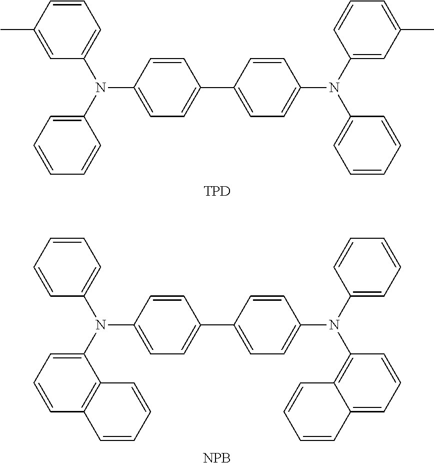

A thickness of the HTL may be from about 50 Å to about 2000 Å, and in some embodiments, may be from about 100 Å to about 1500 Å. When the thickness of the HTL is within these ranges, the HTL may have satisfactory hole transporting abilities without a substantial increase in driving voltage.

The H-functional layer (a functional layer having hole injecting function and hole transporting function simultaneously) may include at least one of the materials used to form the HIL and the HTL as described above, and a thickness of the H-functional layer may be from about 500 Å to about 10000 Å, and in some embodiments, may be from about 100 Å to about 1000 Å. When the thickness of the H-functional layer is within these ranges, the H-functional layer may have satisfactory ability of hole injection and hole transport without a substantial increase in driving voltage.

Meanwhile, at least one of the layers from among the HIL, HTL, and H-functional layer may include one or more compounds represented by Formulas 300 and 350.

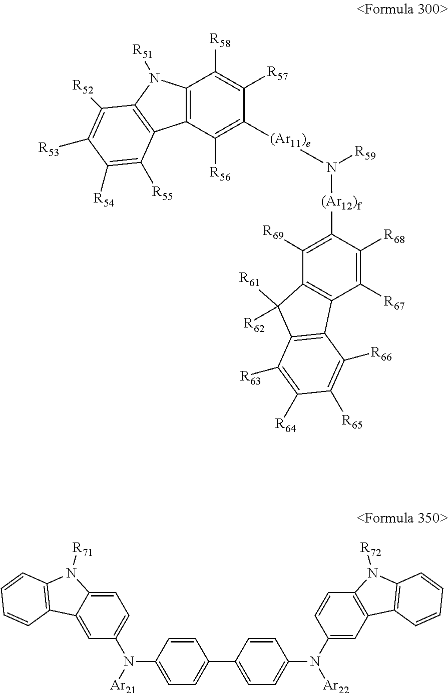

In Formula 300, Ar₁₁ and Ar₁₂ may be each independently a substituted or unsubstituted C₆-C₆₀ arylene group. For example, Ar₁₁ and Ar₁₂ of Formula 300 may be each independently one of a substituted or unsubstituted phenylene group, a substituted or unsubstituted naphthylene group, a substituted or unsubstituted fluorenylene group, or a substituted or unsubstituted anthrylene group, but is not limited thereto. At least one of the substituents from among the substituted phenylene group, substituted naphthylene group, substituted fluorenylene group, and substituted anthrylene group may be a hydrogen atom, a halogen atom, a hydroxyl group, a cyano group, a C₁-C₂₀ alkyl group, a C₁-C₂₀ alkoxy group, a phenyl group, a naphthyl group, an anthryl group, a carbazolyl group, or a carbazolyl group substituted with a phenyl group, but it is not limited thereto.

In Formula 350, Ar₂₁ and Ar₂₂ may be each independently one of a substituted or unsubstituted C₆-C₆₀ aryl group and a substituted or unsubstituted C₂-C₆₀ heteroaryl group. For example, Ar₂₁ and Ar₂₂ in Formula 350 may be each independently one of a substituted or unsubstituted phenyl group, a substituted or unsubstituted naphthyl group, a substituted or unsubstituted phenanthrenyl group, a substituted or unsubstituted anthryl group, a substituted or unsubstituted pyrenyl group, a substituted or unsubstituted chrysenylene group, a substituted or unsubstituted fluorenyl group, a substituted or unsubstituted carbazolyl group, a substituted or unsubstituted dibenzofuranyl group, or a substituted or unsubstituted dibenzothiophenyl group.

Herein, the phenyl group, naphthyl group, phenanthrenyl group, anthryl group, pyrenyl group, chrysenylene group, fluorenyl group, carbazolyl group, dibenzofuranyl group, and dibenzothiophenyl group may be substituted in at least one position by substituents selected from a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₁₀ alkyl group, a C₁-C₁₀ alkoxy group, an aromatic substituent group selected from a phenyl group, a naphthyl group, a fluorenyl group, a phenanthrenyl group, an anthryl group, a triphenylenyl group, a pyrenyl group, a chrysenylene group, an imidazolyl group, an imidazolynil group, an imidazopyridinyl group, an imidazopyrimidinyl group, a pyridinyl group, a pyrazinyl group, a pyrimidinyl group, and an indolyl group, the aromatic substituent group being unsubstituted or substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₁₀ alkyl group, and a C₁-C₁₀ alkoxy group.

In Formula 300, e and f may be each independently an integer from 0 to 5. In Formula 300 above, e may be an integer of 1, and f may be an integer of 0, but they are not limited thereto.

In Formulas 300 and 350, R₅₁ to R₅₈, R₆₁ to R₆₉, and R₇₁, and R₇₂ may be each independently one of a hydrogen atom, a deuterium atom, a halogen atom, a hydroxyl group, a cyano group, —NO₂, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₆-C₆₀ aryl group, a substituted or unsubstituted C₆-C₆₀ aryloxy group, and a substituted or unsubstituted C₆-C₆₀ arylthio group. In some embodiments, R₅₁ to R₅₈, R₆₁ to R₆₉, and R₇₁, and R₇₂ may be each independently one of a hydrogen atom; a deuterium atom; a halogen atom; a hydroxyl group; a cyano group; —NO₂; an amino group; an amidino group; a hydrazine; a hydrazone; a carboxyl group or a salt thereof; a sulfonic acid group or a salt thereof; a phosphoric acid group or a salt thereof; a C₁-C₁₀ alkyl group (e.g., a methyl group, an ethyl group, a propyl group, a butyl group, a pentyl group, a hexyl group, etc); a C₁-C₁₀ alkoxy group (e.g., a methoxy group, an ethoxy group, propoxy group, a butoxy group, a pentoxy group, etc); a C₁-C₁₀ alkyl group or a C₁-C₁₀ alkoxy group that are substituted with at least one of a deuterium atom, a halogen atom, a hydroxyl group, a cyano group, —NO₂, an amino group, an amidino group, a hydrazine, a hydrazone, a carboxyl group or a salt thereof, a sulfonic acid group and a salt thereof, or phosphoric acid group or a salt thereof; and an aromatic group selected from a phenyl group; a naphthyl group; an anthryl group; a fluorenyl group; and a pyrenyl group, the aromatic group being unsubstituted or substituted with at least one of a deuterium atom, a halogen atom, a hydroxyl group, a cyano group, —NO₂, an amino group, an amidino group, a hydrazine, a hydrazone, a carboxyl group or a salt thereof, a sulfonic acid group or a salt thereof, a phosphoric acid group or a salt thereof, a C₁-C₁₀ alkyl group, and a C₁-C₁₀ alkoxy group, but are not limited thereto.

In Formula 300, R₅₉ may be one of a an aromatic group selected from a phenyl group; a naphthyl group; an anthryl group; a biphenyl group; and a pyridyl group, the aromatic groups being unsubstituted or substituted with at least one of a deuterium atom, a halogen atom, a hydroxyl group, a cyano group, —NO₂, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₂₀ alkyl group, and a substituted or unsubstituted C₁-C₂₀ alkoxy group.

According to an embodiment the present invention, the compound represented by Formula 300 above may be represented by Formula 300A below, but is not limited thereto:

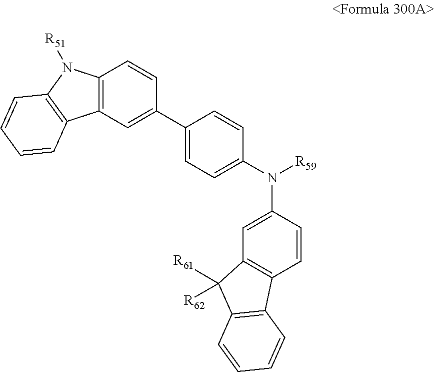

R₅₁, R₆₀, R₆₁, and R₅₉ in Formula 300A may be defined as described above.

For example, at least one of the layers from among the HIL, the HTL, and the H-functional layer may include one of the Compounds 301 to 320, but is not limited thereto:

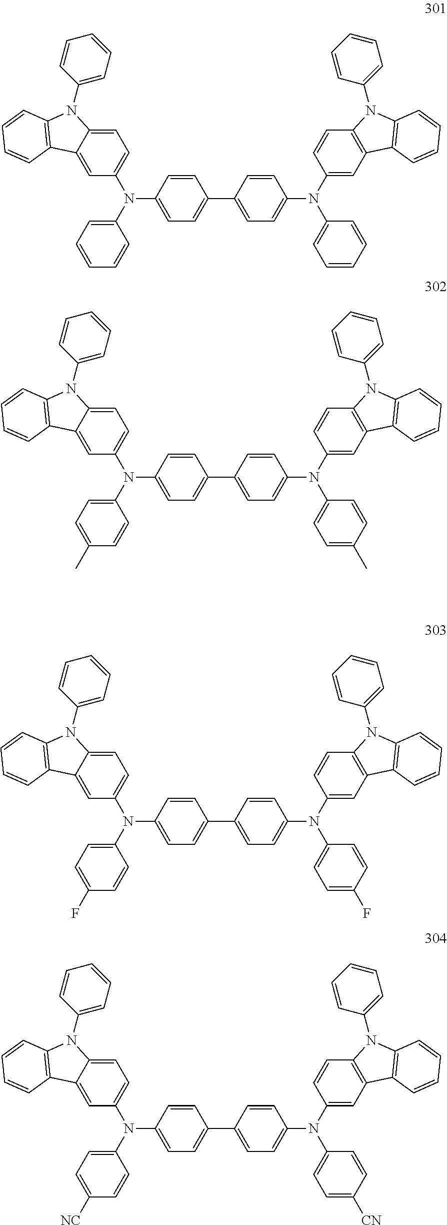 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

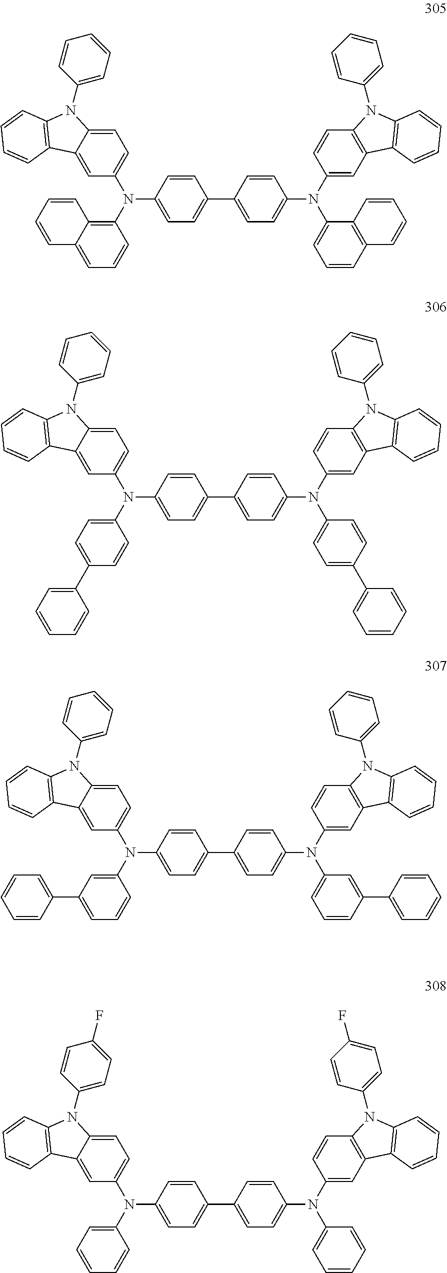 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

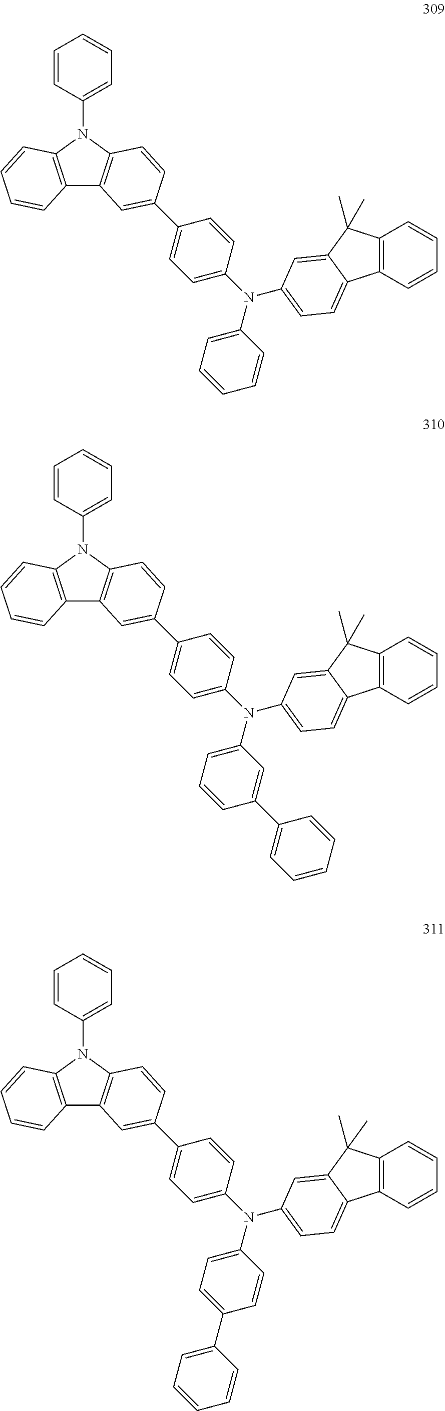 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

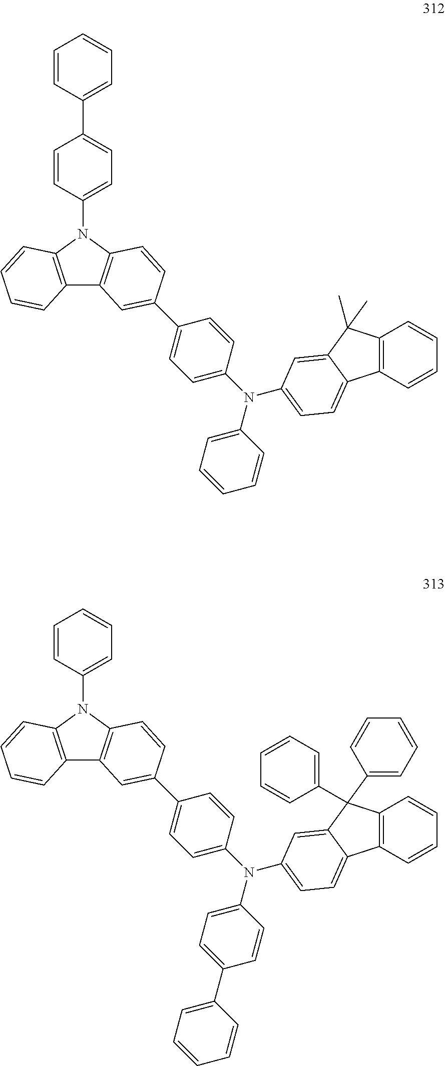 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

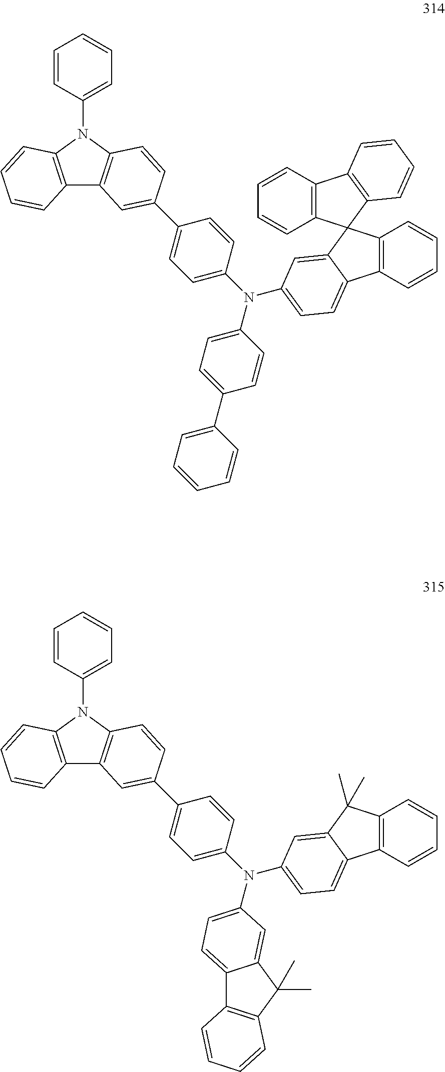 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

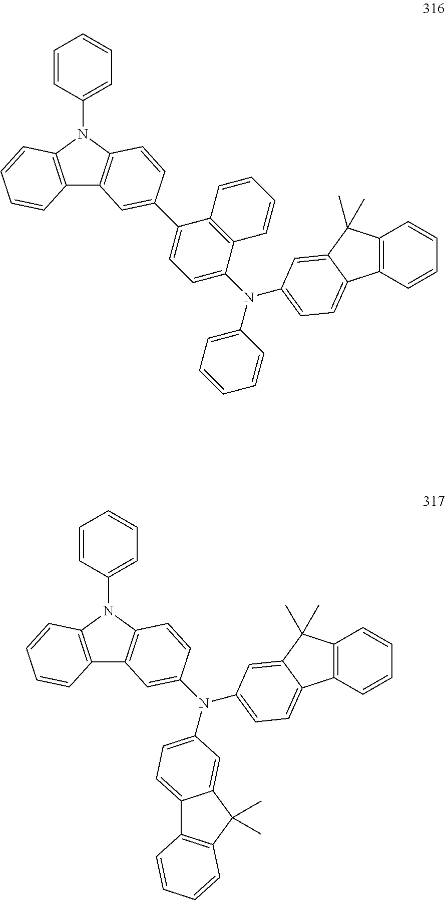 [SMILES: CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21]

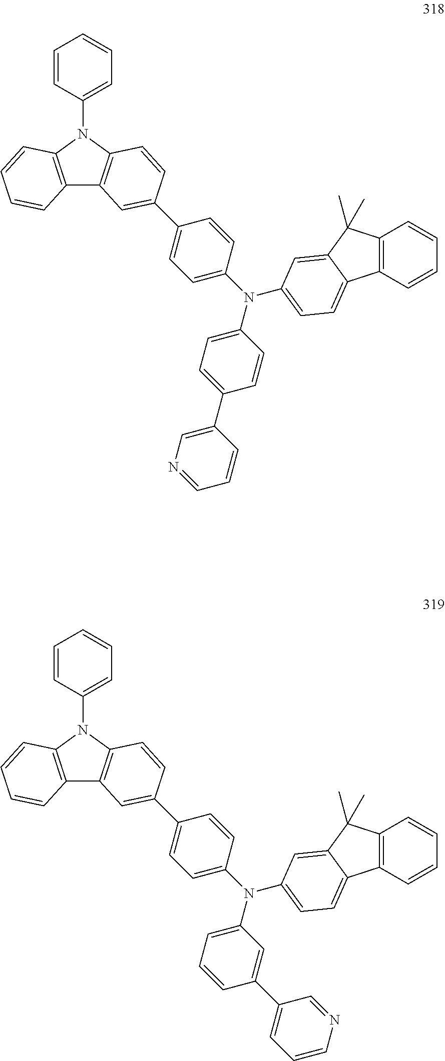 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21]

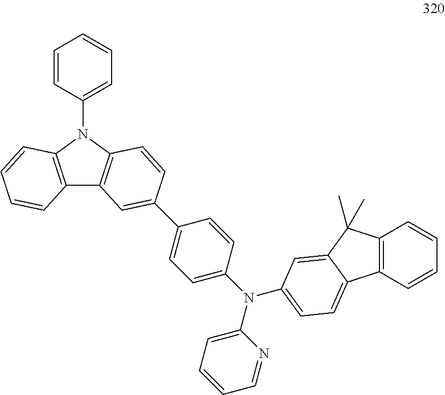 [SMILES: CC1(C)c2ccccc2-c2ccc(N(c3ccc(-c4ccc5c(c4)c4ccccc4n5-c4ccccc4)cc3)c3ccccn3)cc21]

At least one of the HIL, the HTL, and the H-functional layer may further include a charge-generating material to improve layer conductivity, in addition to a known hole injecting material, hole transport material, and/or material having both hole injection and hole transport capabilities as described above.

The charge-generating material may be, for example, a p-dopant. The p-dopant may be one of a quinine derivative, a metal oxide, and a compound with a cyano group, but are not limited thereto. Non-limiting examples of the p-dopant are a quinine derivative such as a tetracyanoquinodimethane (TCNQ) and 2, 3, 5, 6-tetrafluoro-tetracyano-1,4-benzoquinodimethane (F4-TCNQ); a metal oxide such as one of a tungsten oxide and a molybdenum oxide; and a compound with a cyano group such as Formula 200 below, but are not limited thereto.

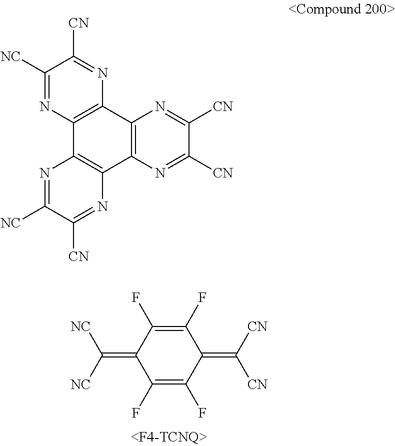 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F]

When one of the HIL, the HTL, and the H-functional layer further includes the charge-generating material, the charge-generating material may be in various modifications, for example, homogeneously dispersed or nonhomogeneously distributed in one of the HIL, the HTL, and the H-functional layer.

A buffer layer may be disposed between the EML and at least one of the HIL, the HTL, and the H-functional layer. The buffer layer may compensate for an optical resonance distance of light according to a wavelength of the light emitted from the EML, and thus may increase efficiency. The buffer layer may include one of a hole injecting material and a hole transporting material. In some other embodiments, the buffer layer may include the same material as one of the materials included in one of the HIL, the HTL and the H-functional layer, the HIL, the HTL and the H-functional layer, if present, underlying the buffer layer.

Then, an EML may be formed on top of one of the HTL, the H-functional layer, and the buffer layer by one of vacuum deposition, spin coating, casting, Langmuir-Blodget (LB) deposition, and the like. When the EML is formed using one of vacuum deposition and spin coating, the deposition and coating conditions may be similar to those employed for the formation of the HIL, though the conditions for deposition and coating may vary according to the material that is used to form the EML.

The EML may include at least one species of the organometallic complex of Formula 1.

The organometallic complex included in the EML may serve as a dopant (e.g., green phosphorescent dopant). Herein, the EML may further include a host in addition to the organometallic complex.

In some embodiments, the host may be a carbazole-based host represented by Formula 100 below, but is not limited thereto.

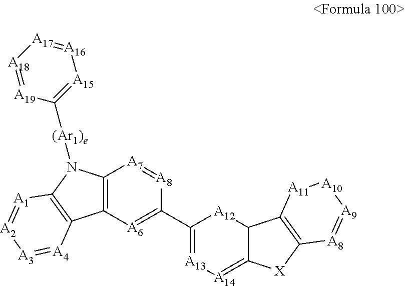

In Formula 100, Aₗ to A₁₉ may be each independently CR₄₁ or N; X may be —C(R₄₂R₄₃)—, —N(R₄₄)—, —S—, —O—, —Si(R₄₅)(R₄₆)—, P(R₄₇)—, —P(═O)(R₄₈)—, or —B(R₄₉)—; An may be one of a substituted or unsubstituted C₆-C₆₀ arylene group and a substituted or unsubstituted C₂-C₆₀ heteroarylene group, but may be excluded (i.e., e=0) if all of A₁₅ to A₁₉ are CR₄₁; R₄₁ to R₄₉ may be each independently one of a hydrogen atom, a deuterium atom, a halogen atom, a hydroxyl group, a cyano group, a nitro group, an amino group, an amidino group, a hydrazine, a a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₂-C₆₀ heteroaryl group, —N(Q₁)(Q₂), —Si(Q₃)(Q₄)(Q₅), and —C(═O)(Q₆) (herein, Q₁ to Q₆ may be each independently one of a hydrogen atom, a substituted or unsubstituted C₁-C₆₀ alkyl group, a substituted or unsubstituted C₆-C₆₀ aryl group, and a substituted or unsubstituted C₂-C₆₀ heteroaryl group), and at least two of R₄₁ to R₄₉ may optionally be connected to each other to form a saturated or unsaturated ring; and e may be integers from 0 to 2.

In Formula 100, X may be —C(R₄₂R₄₃)—, —N(R₄₄)—, —S—, or —O—.

In Formula 100, Ar₁ may be one of a phenylene group, a naphthylene group, a pyridinylene group, a pyrimidinylene group and a triaxylylene group; and a phenylene group, a naphthylene group, a pyridinylene group, a pyrimidinylene group, and a triaxylylene group that are substituted with one of a phenyl group, a naphthyl group, a dimethylfluorenyl group, a pyridinyl group, a pyrymidinyl group, and a triazinyl group.

In Formula 100, R₄₁ to R₄₉ may be each independently one of a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₁₀ alkyl group, a C₁-C₁₀ alkoxy group, a phenyl group, a naphthyl group, a pyridinyl group, a pyrimidinyl group, and a triazinyl group, but is not limited thereto.

The host may be a carbazole-based host represented by one of the following Formulas, but is not limited thereto.

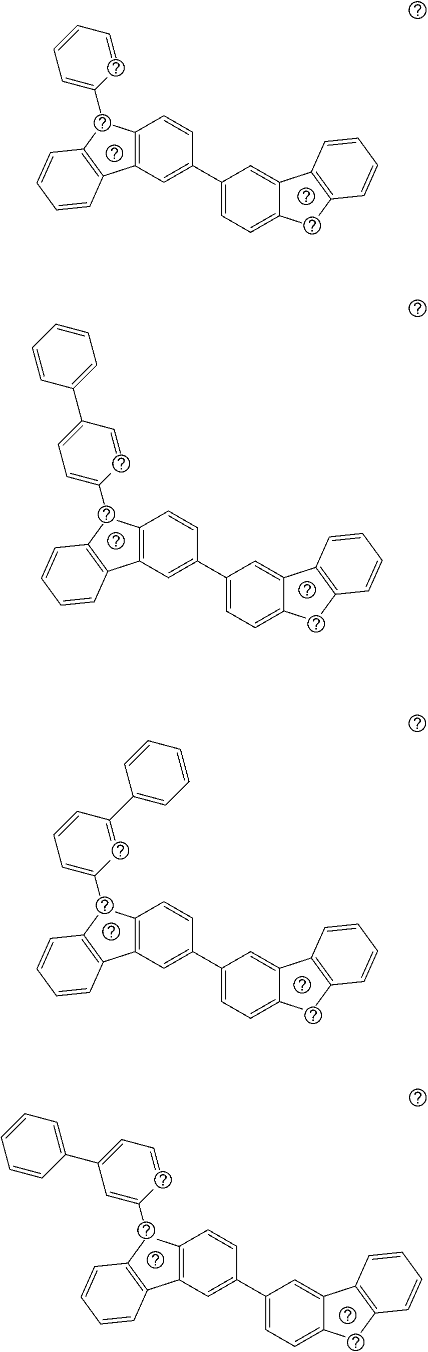

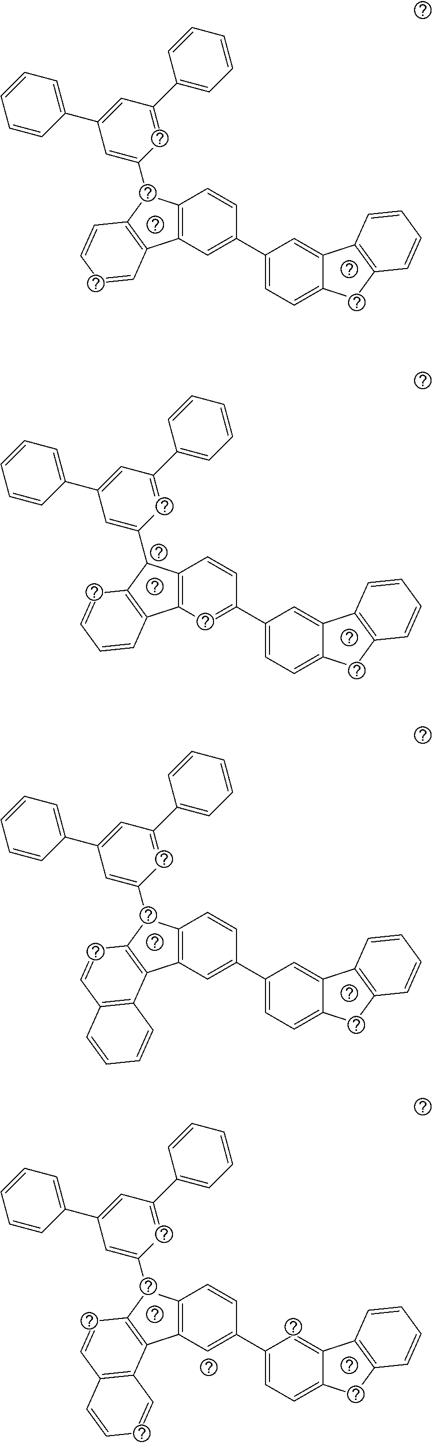

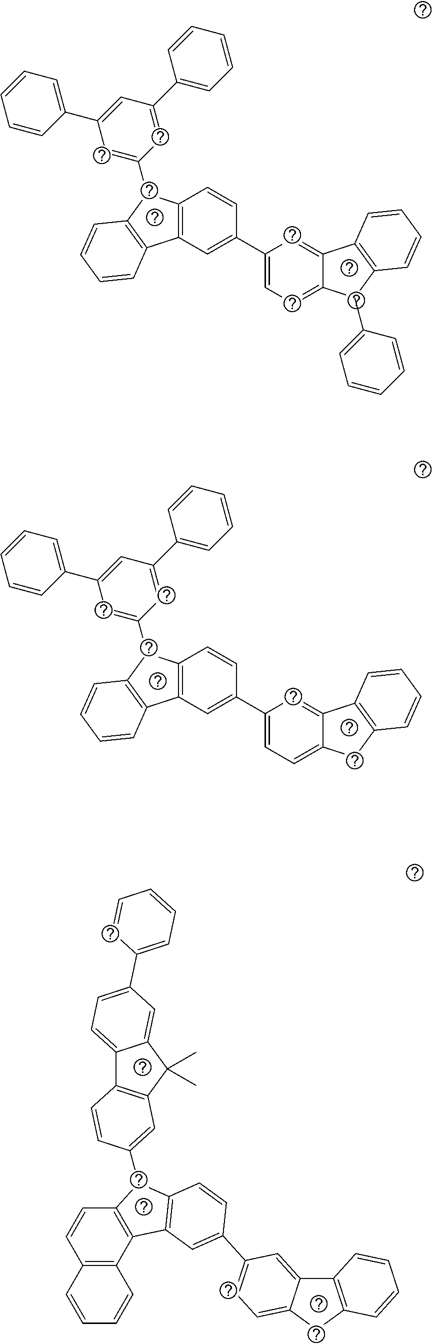

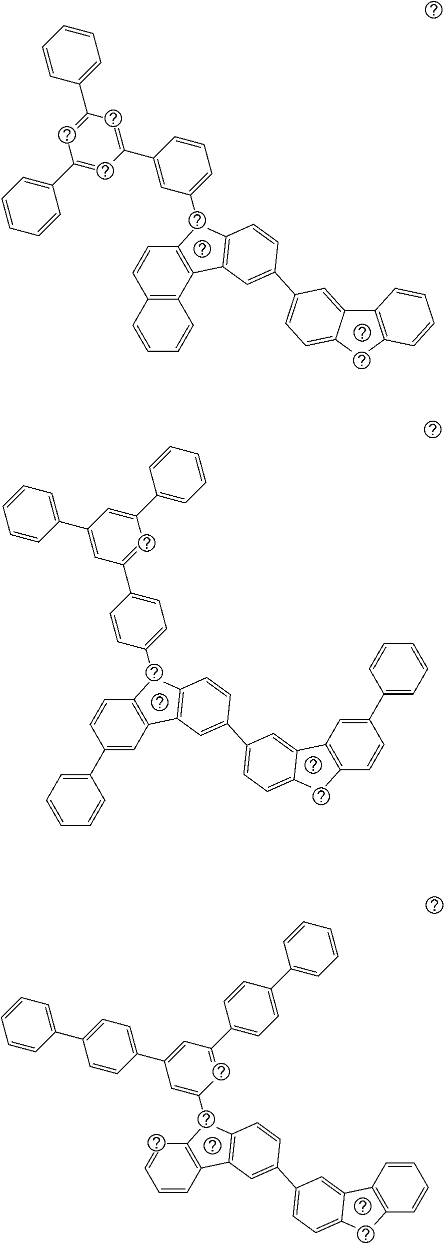

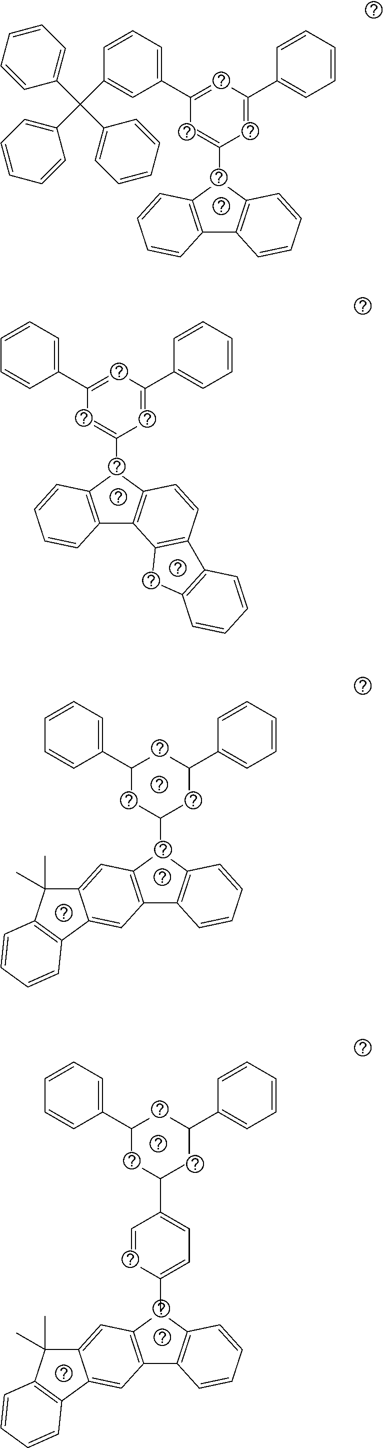

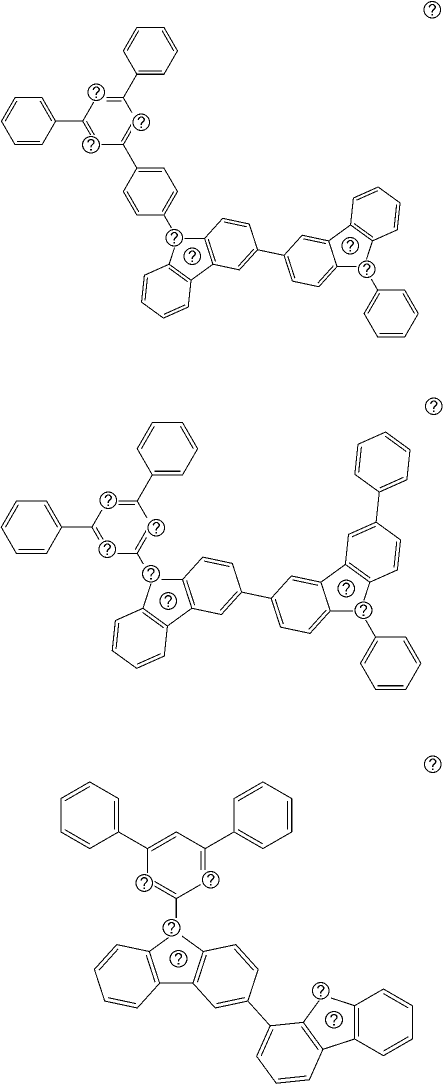

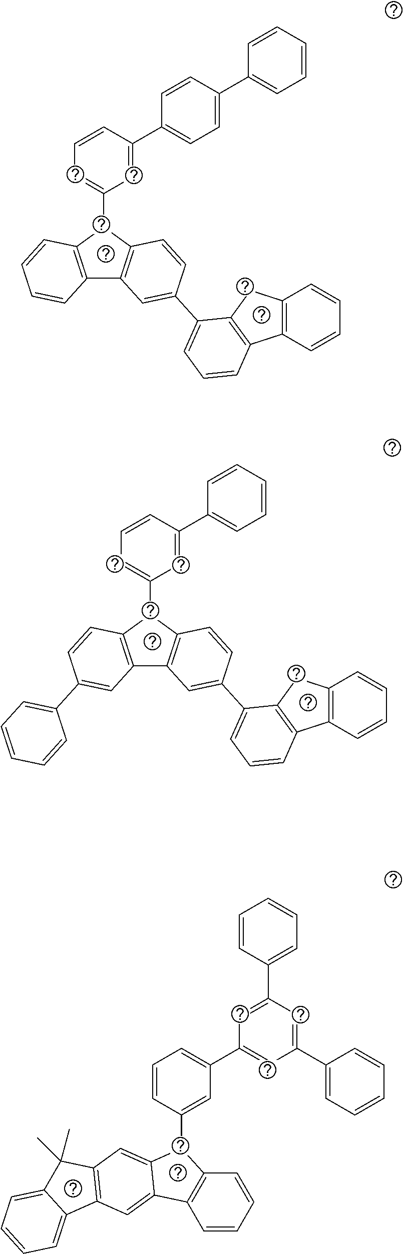

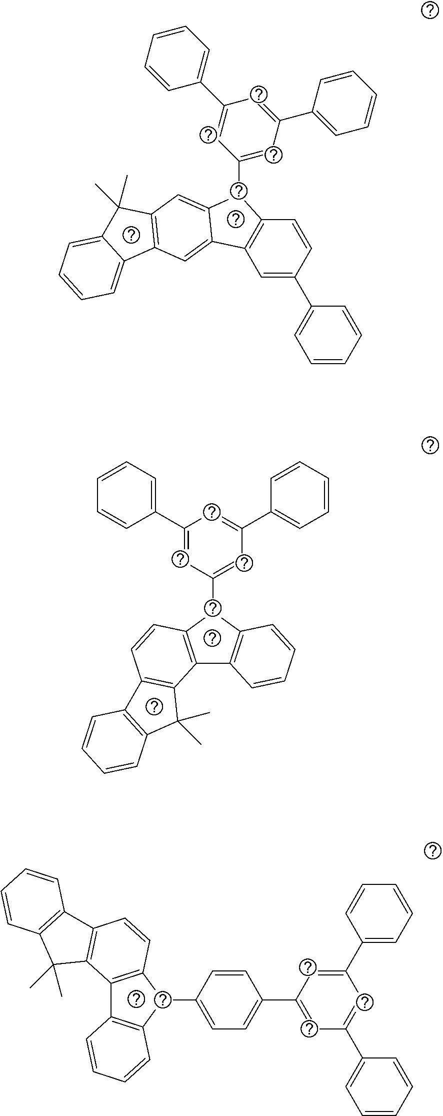

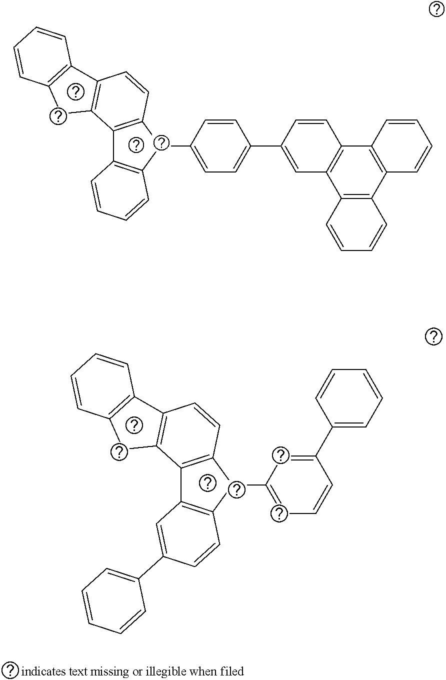

When the EML includes both a host and a dopant (namely, the organometallic complex represented by Formula 1), the amount of the dopant may be from about 0.01 parts to about 15 parts by weight based on 100 parts by weight of the host, but is not limited thereto.

A thickness of the EML may be from about 200 Å to about 700 Å. When the thickness of the EML is within this range, the EML may have improved light-emitting ability without a driving voltage that is substantially too high.

Next, an electron transport layer (ETL) may be formed on top of the EML using various methods such as vacuum deposition, spin coating, casting, and Langmuir Blodgett (LB) deposition. When the ETL is formed using one of vacuum deposition and spin coating, the deposition and coating conditions may be similar to those for the formation of the HIL, though the deposition and coating conditions may vary depending upon the compound that is used to form the ETL. The ETL-forming materials function as to stabilize transport of injected electrons injected from a cathode and may comprise electron transporting materials. Examples of known electron transporting materials are quinoline derivatives, diazines and triazines, including, more particularly, tris-(8-hydroxyquinoline)aluminum (Alq3), 4-phenyl-5-(4-biphenylyl)-3-(4-tert-butylphenyl)-1,2,4-triazine (TAZ), bis(2-methyl-8-quinolinato)-4-phenylphenolate aluminum (Balq), beryllium bis(benzoquinolin-10-olate) (Bebq2), ADN, Compound 201, and Compound 202, but are not limited thereto.

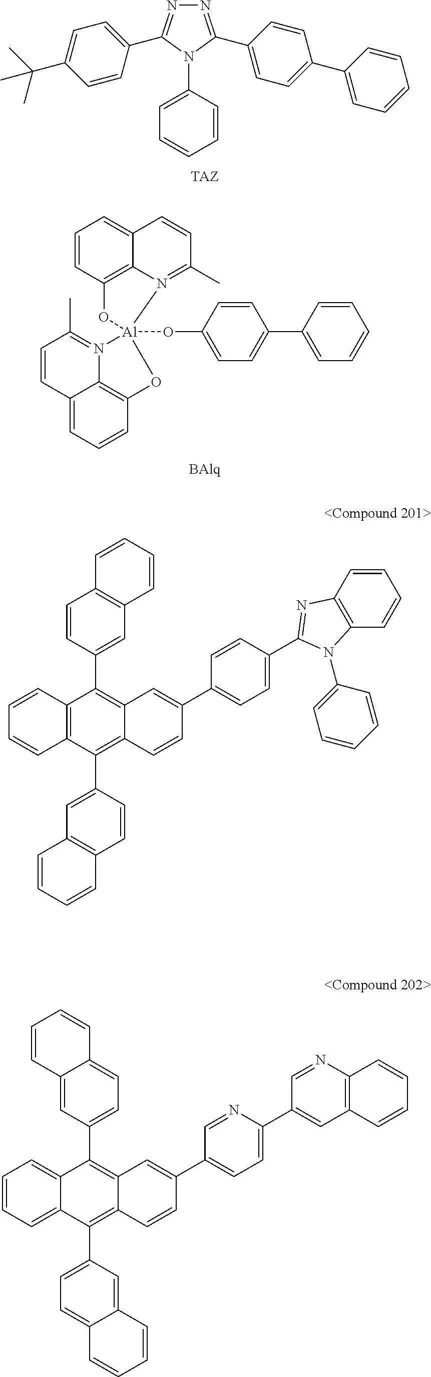

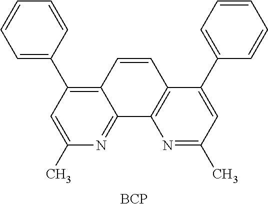

A thickness of the ETL may be from about 100 Å to about 1000 Å, and, in some embodiments, may be from about 150 Å to about 500 Å. When the thickness of the ETL is within these ranges, the ETL may have satisfactory electron transporting ability without a driving voltage that is substantially too high.

In addition, the ETL may further include metal-containing material in addition to a known electron transporting organic compound.

The metal-containing compound may include a lithium (Li) complex. Non-limiting examples of the Li complex are lithium quinolate (LiQ) and Compound 203 below:

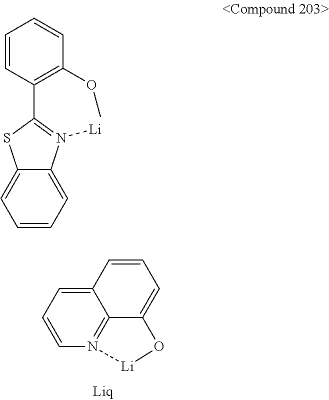

Also, an electron injection layer (EIL), which facilitates injection of electrons from the cathode, may be formed on top of the ETL. Any suitable electron-injecting material may be used to form the EIL.

Non-limiting examples of materials for forming the EIL may be LiF, NaCl, CsF, Li₂O, BaO, and the like, which are known in the art. The deposition conditions may be similar to those used to form the HIL, although the deposition conditions may vary according to the material that is used to form the EIL.

A thickness of the EIL may be from about 1 Å to about 100 Å, and, in some embodiments, may be from about 3 Å to about 90 Å. When the thickness of the ETL is within these ranges, the ETL may have satisfactory electron transporting ability without a driving voltage that is substantially too high.

A second electrode 17 is disposed on top of the organic layer 15. The second electrode 17 may be a cathode, which is an electron injecting electrode. Herein, the second electron-forming material may be a metal, an alloy, an electrically conductive compound having a low-work function, or a mixture thereof. In this regard, the second electrode 17 may be formed of lithium (Li), magnesium (Mg), aluminum (Al), aluminum-lithium (Al—Li), calcium (Ca), magnesium-indium (Mg—In), magnesium-silver (Mg—Ag), or the like, and may be formed as a thin film type transmission electrode. In some embodiments, to manufacture a top-emission light-emitting device, the transmission electrode may be formed in various modifications like indium tin oxide (ITO) or indium zinc oxide (IZO).

So far, the OLED has been described with reference to FIG. 1, but it is not limited thereto.

In addition, when the EML is formed using a phosphorescent dopant, to prevent diffusion of triplet excitons or holes toward the ETL, a hole blocking layer (HBL) may be formed between the HTL and the EML or between the H-functional layer and the EML by a method such as one of vacuum deposition, spin coating, casting, Langmuir-Blodgett (LB), and the like. When the HBL is formed using one of vacuum deposition and spin coating, the conditions for deposition and coating may be similar to those used for the formation of the although the conditions for deposition and coating may vary according to the compound that is used to form the HBL. Any known hole-blocking material may be used. Examples of hole-blocking materials may be selected from oxadiazole derivatives, triazole derivatives, and phenanthroline derivatives. In particular, 2,9-dimethyl-4,7-diphenylphenanthroline (BCP), shown below, may be used as a hole-blocking material.

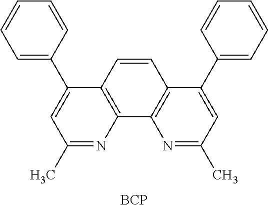

A thickness of the HBL may be from about 20 Å to about 1000 Å, and in some embodiments, may be from about 30 Å to about 300 Å. When the thickness of the HBL is within these ranges, the HBL may have improved hole blocking ability without imparting a driving voltage that is substantially too high.

Examples of the unsubstituted C1-C60 alkyl group (or a C1-C60 alkyl group) used herein may be linear or branched C1-C60 alkyl group, such as methyl group, ethyl group, propyl group, isobutyl group, sec-butyl group, pentyl group, iso-amyl group, hexyl group, or the like. In the substituted C1-C60 alkyl group, at least one hydrogen atom of the unsubstituted C1-C60 alkyl group described above may be substituted with one of a deuterium atom; —F; —Cl; —Br; —I; —CN; a hydroxyl group; —NO2; an amino group; an amidino group; a hydrazine; a hydrazone; a carboxyl group or a salt thereof; a sulfonic acid group or a salt thereof; a phosphoric acid group or a salt thereof; a tri(C6-C60 aryl)silyl group; and a hydrocarbon substituent group comprising a C1-C60 alkyl group, a C1-C60 alkoxy group, a C2-C60 alkenyl group, and a C2-C60 alkynyl group, the hydrocarbon substituent groups being optionally substituted with one of a deuterium atom, —F, —Cl, —Br, —I, —CN, a hydroxyl group, —NO2, an amino group, an amidino group, a hydrazine, a hydrazone, a carboxyl group or a salt thereof, a sulfonic acid group or a salt thereof, and a phosphoric acid group or a salt thereof. In the substituted C1-C60 alkyl group, at least one hydrogen atom of the unsubstituted C1-C60 alkyl group described above may be substituted with one of a substituent group comprising a C3-C60 cycloalkyl group, a C3-C60 cycloalkenyl group, a C6-C60 aryl group, a C2-C60 heteroaryl group, a C6-C60 aralkyl group, a C6-C60 aryloxy group, and a C6-C60 arylthio group, the substituent group being optionally substituted with at least one of a deuterium atom, —F, —Cl, —Br, —I, —CN, a hydroxyl group, —NO2, an amino group, an amidino group, a hydrazine, a hydrazone, a carboxyl group or a salt thereof, a sulfonic acid group or a salt thereof, a phosphoric acid group or a salt thereof, a C1-C60 alkyl group, and a C1-C60 alkyl group that is substituted with at least one of F, a C1-C60 alkoxy group, a C2-C60 alkenyl group, a C2-C60 alkynyl group, a C6-C60 aryl group, and a C2-C60 heteroaryl group.

The unsubstituted C1-C60 alkoxy group (or the C1-C60 alkoxy group) used herein may have Formula of —OA (wherein A is an unsubstituted C1-C60 alkyl group as described above), and examples are a methoxy, an ethoxy, an isopropyloxy, or the like. At least one hydrogen atom in the alkoxy group may be substituted with a substituent as described above in conjunction with the C1-C60 alkyl group.

The unsubstituted C2-C60 alkenyl group (or the C2-C60 alkenyl group) used herein may be a hydrocarbon chain having a carbon-carbon double bond in the center or at a terminal of the unsubstituted C2-C60 alkyl group. Examples of the unsubstituted C2-C60 alkenyl group may include an ethenyl group, a propenyl group, a butenyl group, and the like. At least one hydrogen atom in the C2-C60 alkenyl group may be substituted with a substituent as described above in conjunction with the C1-C60 alkyl group.

The unsubstituted C2-C60 alkynyl group (or the C2-C60 alkynyl group) used herein may be a hydrocarbon chain having at least one carbon-carbon triple bond in the center or at a terminal of the C2-C60 alkyl group. Examples of the unsubstituted C2-C60 alkynyl group include an ethynyl group, a propynyl group, and the like. At least one hydrogen atom in the alkynyl group may be substituted with a substituent as described above in conjunction with the C1-C60 alkyl group.

The unsubstituted C3-C60 cycloaryl group used herein may be a monovalent group having a saturated cyclohydrocarbon having 3 to 60 carbons, and examples of the saturated cyclohydrocarbon include a cyclopropyl group, a cyclobutyl group, a cyclopentyl group, a cyclohexyl group, a cyclooctyl, and the like. At least one hydrogen atom in the cycloalkyl group may be substituted with a substituent as described above in conjunction with the C1-C60 alkyl group.

The unsubstituted C3-C60 cycloalkenyl group used herein may have at least one carbon-carbon double bond and no aromatic ring. Examples of the unsaturated cyclohydrocarbons include a cyclopropenyl group, a cyclobutenyl group, a cyclopentenyl group, a cyclohexenyl group, a cycloheptenyl group, a 1,3-cyclohexadienyl group, a 1,4-cyclohexadienyl group, a 2,4-cycloheptydienyl group, a 1,5-hychlooctadienyl group, and the like. At least one of the hydrogen atoms in the cycloalkenyl group may be substituted with a substituent as described above in conjunction with the C1-C60 alkyl group.

The unsubstituted C6-C60 aryl group used herein may be a monovalent group having a carbocyclic aromatic system having 6 to 60 carbon atoms including at least one aromatic ring. The unsubstituted C6-C60 arylene group may be a bivalent group having a carbocyclic aromatic system having 6 to 60 carbon atoms including at least one aromatic ring. When the aryl group and the arylene group have at least two rings, the two rings may be fused to each other. At least one hydrogen atom in the aryl group and arylene group may be substituted with a substituent as described above in conjunction with the C1-C60 alkyl group.

Examples of the substituted or unsubstituted C6-C60 aryl group may be one of a phenyl group, a C1-C10 alkylphenyl group (e.g., an ethylphenyl group), a C1-C10 alkylbiphenyl group (e.g., an ethylbiphenyl group), a halophenyl group (e.g., o-, m-, or p-fluorophenyl group, and a dichlorophenyl group), a dicyanophenyl group, a trifluoromethoxyphenyl group, o-, m-, or p-tolyl, o-, m- or p-cumenyl, a mesityl group, a phenoxyphenyl group, (a,a-dimethylbenzene)phenyl group, a (N,N′-dimethyl)aminophenyl group, a (N,N′-diphenyl)aminophenyl group, a pentalenyl group, a indenyl group, a naphthyl group, a halonaphthyl group (e.g., a fluoronaphthyl group), a C1-C10 alkylnaphthyl group a methylnaphthyl group), a C1-C10 alkoxynaphthyl group (e.g., a methoxynaphthyl group), an anthracenyl group, an azulenyl group, a heptalenyl group, an acenaphthylenyl group, a fluorenyl group, an anthraquinolyl group, a methylanthryl group, a phenanthryl group, a triphenylenyl group, a pyrenyl group, a chrysenyl group, an ethyl-chrysenyl group, a picenyl group, a perylenyl group, a chloroperylenyl group, a pentaphenyl group, a pentacenyl group, a tetraphenylenyl group, a hexaphenyl group, hexacenyl group, a rubicenyl group, a coronenyl group, a trinaphthylenyl group, a heptaphenyl group, a heptacenyl group, a pyranthrenyl group, and an ovalenyl group, and the like. Examples of the substituted C6-C60 aryl group may be inferred based on corresponding examples of the unsubstituted C6-C60 aryl group and the substituted C1-C60 alkyl group. Examples of the substituted or unsubstituted C6-C60 arylene group may be inferred based on those examples of the substituted or unsubstituted C6-C60 aryl group described above.

The unsubstituted C2-C60 heteroaryl group used herein may be a monovalent group having at least one aromatic ring, the at least one aromatic ring having at least one of the heteroatoms selected from the group consisting of N, O, P, and S as a ring-forming atom. The unsubstituted C2-C60 heteroarylene group may be a divalent group having at least one aromatic ring, the aromatic ring including at least one of the heteroatoms selected from the group consisting of N, O, P, and S. In this regard, when the heteroaryl group and the heteroarylene group have at least two rings, the two rings may be fused to each other. At least one hydrogen atom in the heteroaryl group and the heteroarylene group may be substituted with the substituent described above in conjunction with the C1-C60 alkyl group.

Examples of the unsubstituted C2-C60 heteroaryl group include a pyrazolyl group, an imidazolyl group, an oxazolyl group, a thiazolyl group, tetrazolyl group, an oxadiazolyl group, a pyridinyl group, a pyridazinyl group, a pyrimidinyl group, a triazinyl group, a carbazolyl group, an indolyl group, a quinolinyl group, an isoquinolinyl group, a benzoimidazolyl group, an imidazopyridinyl group and an imidazopyrimidinyl group, and the like. Examples of the unsubstituted and substituted C2-C60 heteroarylene group may be inferred based on the examples of unsubstituted and substituted C2-C60 arylene groups described above.

The substituted or unsubstituted C6-C60 aryloxy group is denoted by —OA2 (A2 being a substituted or unsubstituted C6-C60 aryl group as described above). The substituted or unsubstituted C6-C60 arylthio group is denoted by —SA3 (A3 being a substituted or unsubstituted C6-C60 aryl group as described above).

### EXAMPLE 1

### SYNTHESIS EXAMPLE 1

### Synthesis of Complex 1

Complex 1 was synthesized according to Reaction Scheme 1 below.

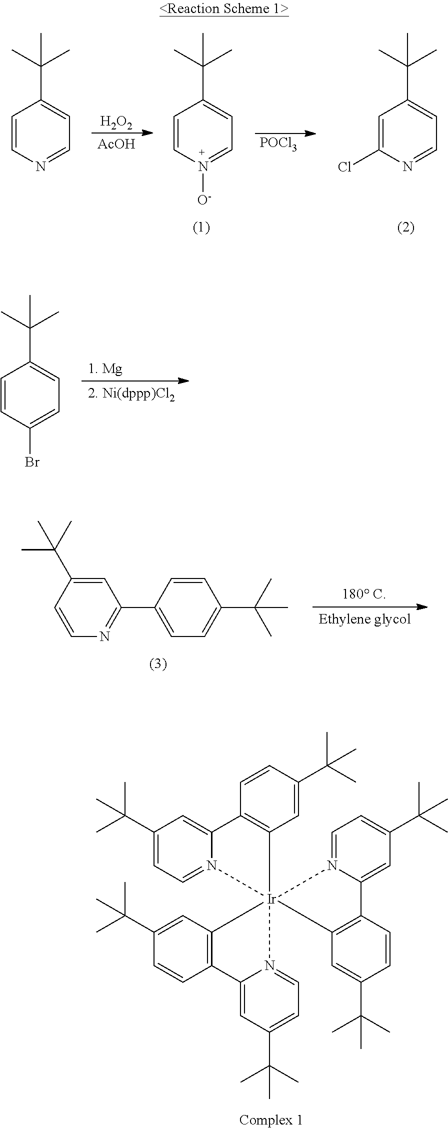

### Synthesis of Intermediate (1) (4-(tert-butyl)pyridine N-oxide)

After adding 50 g (0.37 mol) of 4-(tert-butyl)pyridine to 240 mL of acetic acid contained in a 500 mL 3-necked round bottom flask, 50.3 mL (0.44 mol) of 30% hydrogen peroxide was added thereto, and the mixture was then heated under reflux overnight in a nitrogen atmosphere. The solvent was removed from the resulting reaction mixture, and the temperature was cooled down to room temperature. The residue was neutralized with NaOH solution, then extracted with dichloromethane. After removing the moisture from the resulting reaction product mixture using anhydrous MgSO4, the solvent was removed to obtain 52 g (Yield: 95%) of Intermediate (1), (4-(tert-butyl)pyridine N-oxide).

### Synthesis of Intermediate (2) (4-(tert-butyl)-2-chloropyridine)

After adding 150 mL (1.59 mol) of POCl3 to a 500 mL (1.59 mol) 3-necked round bottom flask, 40 g (0.26 mol) of Intermediate (1) (4-(tert-butyl)pyridine N-oxide) was added thereto, and the mixture was then heated under reflux overnight in a nitrogen After completion of the reaction, POCl3 was removed and neutralized, and the product residue was then extracted with chloroform. After removing the moisture from the resulting reaction mixture using anhydrous MgSO4, the solvent was removed. The resulting product was purified by distillation to obtain 21.5 g (Yield: 48%) of Intermediate (2) (4-(tert-butyl)-2-chloropyridine).

1H-NMR (300 MHz, CD2Cl2, δ ppm): 8.13 (d, 1H), 7.15 (s, 1H), 7.08 (d, 1H), 1.15 (s, 9H)

### Synthesis of Intermediate (3) (4-(tert-butyl)-2-(4-(tert-butyl)phenyl)pyridine)

After adding 1.14 g (46.92 mmol) of Mg and 50 mL of diethyl ether to a 100 mL 3-necked round bottom flask in a nitrogen atmosphere, 10 g (46.92 mmol) of 1-bromo-4-(tert-butyl)benzene was added thereto, then stirred for about 3 hours to obtain the corresponding Grignard reagent. After adding 5.3 g (31.28 mmol) of Intermediate (2) (4-(tert-butyl)-2-chloropyridine) and 0.17 g (0.31 mmol) of Ni(dppp)Cl2 to 50 mL of diethyl ether contained in a 250 mL 3-neck flask, followed by stirring, the diethyl ether solution of the Grignard reagent was dropwise added thereto, and the resulting mixture was allowed to react overnight. After quenching the reaction mixture by adding water thereto, the resulting reaction mixture was extracted with ethyl acetate. After removing the moisture from the resulting reaction mixture using anhydrous MgSO4, the solvent was removed. The resulting reaction mixture was purified using column chromatography to obtain 5.1 g (Yield: 61%) of Intermediate (3) (4-(tert-butyl)-2-(4-(tert-butyl)phenyl)pyridine).

1H-NMR (300 MHz, CD2Cl2, δ ppm): 8.58 (d, 1H), 7.96 (d, 2H), 7.76 (s, 1H), 7.53 (d, 2H), 7.27 (q, 1H), 1.40 (s, 18H)

Synthesis of Complex 1

After adding 1.32 g (4.92 mmol) of Intermediate (3) (4-(tert-butyl)-2-(4-(tert-butyl)phenyl)pyridine) and 0.73 g (1.49 mmol) of iridium acetylacetonate to a 50 mL 3-necked round bottom flask, 10 mL of ethylene glycol was added thereto. After degassing, the resulting reaction mixture was stirred at 180 C for 24 hours, and the temperature was allowed to cool to room temperature. After adding water to and stirring the resulting reaction mixture, the resulting reaction mixture was filtered with a filter, and the filtered crude product was washed with EtOH, then purified using column chromatography to obtain 0.55 g (Yield: 37%) of Complex 1.

1H-NMR (300 MHz, CD2Cl2, δ ppm): 7.88 (s, 3H), 7.61 (d, 3H), 7.51 (d, 3H), 6.90 (m, 9H), 1.38 (s, 27H), 1.11 (s, 18H)

### SYNTHESIS EXAMPLE 2

### Synthesis of Complex 2

Complex 2 was synthesized according to Reaction Scheme 2:

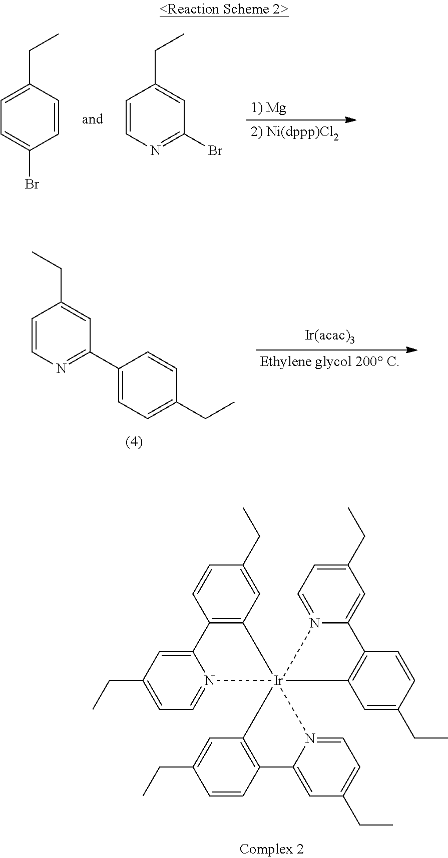

### Synthesis of Intermediate (4) (4-ethyl-2-(4-ethylphenyl)pyridine)

After adding 0.85 g (34.93 mmol) of Mg and 50 mL of diethyl ether to a 100 mL 3-round bottom flask in a nitrogen atmosphere, 6.42 g (34.93 mmol) of 1-bromo-4-ethylbenzene was added thereto, then stirred for about 3 hours to obtain the corresponding Grignard reagent. After adding 4.5 g (26.87 mmol) of 2-bromo-4-ethylpyridine and 0.15 g (0.27 mmol) of Ni(dppp)Cl2 to 50 mL of diethyl ether contained in a 250 mL 3-necked flask, followed by stifling, the diethyl ether solution of the Grignard reagent was dropwise added thereto, then allowed to react overnight. After quenching the reaction mixture by adding water thereto, the resulting reaction mixture was extracted with ethyl acetate. After removing the moisture from the resulting reaction mixture using anhydrous MgSO4, the solvent was removed. The resulting reaction product mixture was purified using column chromatography to obtain 3.7 g (Yield: 65%) of Intermediate (4).

1H-NMR (300 MHz, CD2Cl2, δ ppm): 8.52 (d, 1H), 8.00 (d, 2H), 7.76 (s, 1H), 7.30 (d, 2H), 7.15 (d, 1H), 2.62 (m, 4H), 1.22 (m, 6H)

Synthesis of Complex 2

0.67 g (Yield: 32%) of Complex 2 was synthesized in the same manner as in the synthesis of Compound 1 of Synthesis Example 1, except that Intermediate (4), instead of Intermediate (3), was used in synthesizing Complex 2.

1H-NMR (300 MHz, CD2Cl2, δ ppm): 7.72 (s, 3H), 7.60 (d, 3H), 7.42 (d, 3H), 6.75 (m, 9H), 2.74 (q, 6H), 2.38 (q, 6H), 1.30 (t, 9H), 1.07 (t, 9H)

### SYNTHESIS EXAMPLE 3

### Synthesis of Complex 3

Complex 3 was synthesized according to Reaction Scheme 3:

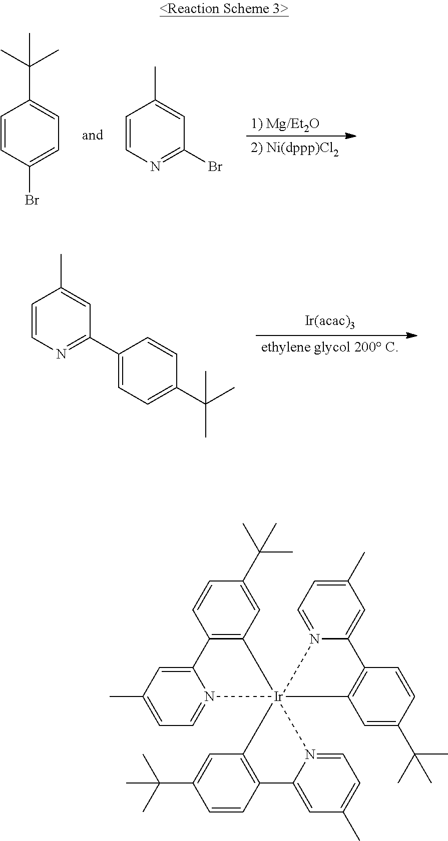

### Synthesis of Intermediate 5 (2-(4-tert-butylphenyl)-4-methylpyridine)

After adding 1.65 g (68.02 mmol) of Mg and 90 mL of diethyl ether to a 250 mL round bottomed flask in a nitrogen atmosphere, 14.5 g (68.02 mmol) of 1-bromo-4-tert-butylbenzene was added thereto, and the reaction mixture was stirred for about 3 hours to obtain the corresponding Grignard reagent. After adding 9 g (52.32 mmol) of 2-bromo-4-methylpyridine, 0.28 g (0.52 mmol) of Ni(dppp)Cl₂, and 50 mL of diethyl ether to a 500 mL 3-necked flask and stifling, the diethyl ether solution of the Grignard reagent was dropwise added thereto, and the mixture was allowed to react overnight. After quenching of the reaction mixture by adding water thereto, the resulting reaction mixture was extracted with ethyl acetate. After removing the moisture from the resulting ethyl acetate extracts using anhydrous MgSO₄, the solvent was removed. The resulting reaction mixture was purified using column chromatography to obtain 7.3 g (Yield: 62%) of 2-(4-tert-butylphenyl)-4-methylpyridine.

1H-NMR (300 MHz, CD2Cl2, δ ppm): 8.55 (d, 1H), 8.01-7.96 (d, 2H), 7.61 (s, 1H), 7.56-7.52 (d, 2H), 7.08 (d, 1H), 2.44 (s, 3H), 1.41 (s, 9H).

### Synthesis of Complex 3

After adding 1 g (4.44 mmol) of 2-(4-tert-butylphenyl)-4-methylpyridine obtained from the previous synthesis and 0.658 g (1.34 mmol) iridium acetylacetonate to a 50 mL 3-necked round bottom flask, 10 mL of ethylene glycol was added thereto. After degassing, the resulting reaction mixture was stirred at 200° C. for 24 hours, and the temperature was then cooled down to a room temperature. After adding water to and stirring the resulting reaction mixture, the resulting reaction mixture was filtered with a filter, and the filtered crude product was washed with EtOH, then purified using column chromatography to obtain 0.4 g (Yield: 34%) of Complex 3.

1H-NMR (300 MHz, CD2Cl2, δ ppm): 7.69 (s, 3H), 7.56-7.53 (d, 3H), 7.50 (d, 3H), 6.92 (d, 6H), 6.79-6.76 (d, 3H), 2.44 (s, 9H), 1.09 (s, 27H)

### SYNTHESIS EXAMPLE 4

### Complex 4

Complex 4 was synthesized according to Reaction Scheme 4:

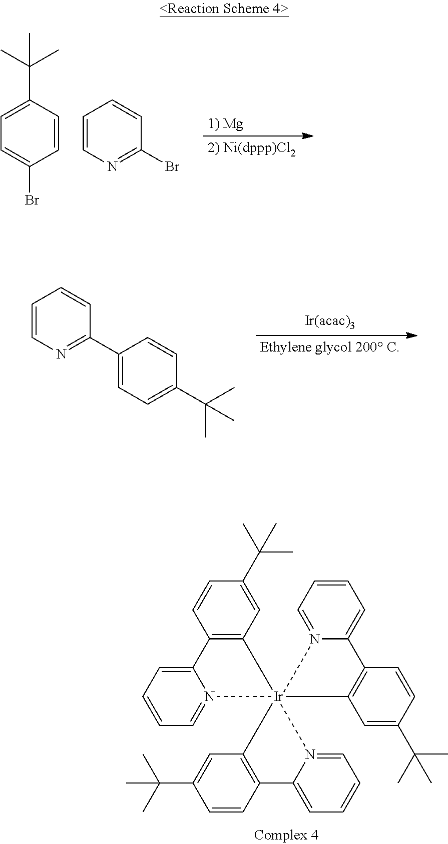

### Synthesis of 2-(4-tert-butylphenyl)pyridine

After adding 2 g (82.28 mmol) of Mg and 100 mL of diethyl ether to a 250 mL round bottom flask in a nitrogen atmosphere, 17.5 g (82.28 mmol) of 1-bromo-4-tert-butylbenzene was added thereto, and the reaction mixture was then stirred for about 3 hours to obtain the corresponding Grignard reagent. After adding 10 g (63.29 mmol) of 2-bromopyridine, 0.35 g (0.63 mmol) of Ni(dppp)Cl₂, and 80 mL of diethyl ether to a 500 mL 3-neck-flask and stirring, the Grignard reagent was dropwise added thereto, and the mixture was allowed to react overnight. After quenching of the reaction by adding water thereto, the resulting reaction product mixture was extracted with ethyl acetate. After removing the moisture from the ethyl acetate extracts using anhydrous MgSO₄, the solvent was removed. The resulting crude reaction product mixture was purified using column chromatography to obtain 6.5 g (Yield: 48%) of 2-(4-tert-butylphenyl)pyridine.

1H-NMR (300 MHz, CD2Cl2, δ ppm): 8.70 (d, 1H), 8.01(d, 2H), 7.78 (m, 2H), 7.56 (d, 1H), 7.25 (m. 1H), 1.43 (s, 9H).

Synthesis of Complex 4

After adding 1 g (4.73 mmol) of 2-(4-tert-butylphenyl)pyridine and 0.702 g (1.43 mmol) of iridium acetylacetonate to a 50 mL 3-necked round bottom flask, 10 mL of ethylene glycol was added thereto. After degassing, the resulting reaction mixture was stirred at 200° C. for 24 hours, and the temperature of the resulting mixture then was cooled to room temperature. After adding water to and stifling the resulting reaction mixture, the resulting reaction mixture was filtered with a filter, and the filtered crude reaction product was washed with EtOH, then purified using column chromatography to obtain 0.45 g (Yield: 38%) Complex 4.

1H-NMR (300 MHz, CD2Cl2, δ ppm): 7.90 (d, 3H), 7.67-7.57 (m, 9H), 6.97-6.92 (m, 9H), 1.10 (s, 27H)

### SYNTHESIS EXAMPLE 5

### Synthesis of Complex 5

Complex 5 was synthesized according to Reaction Scheme 5:

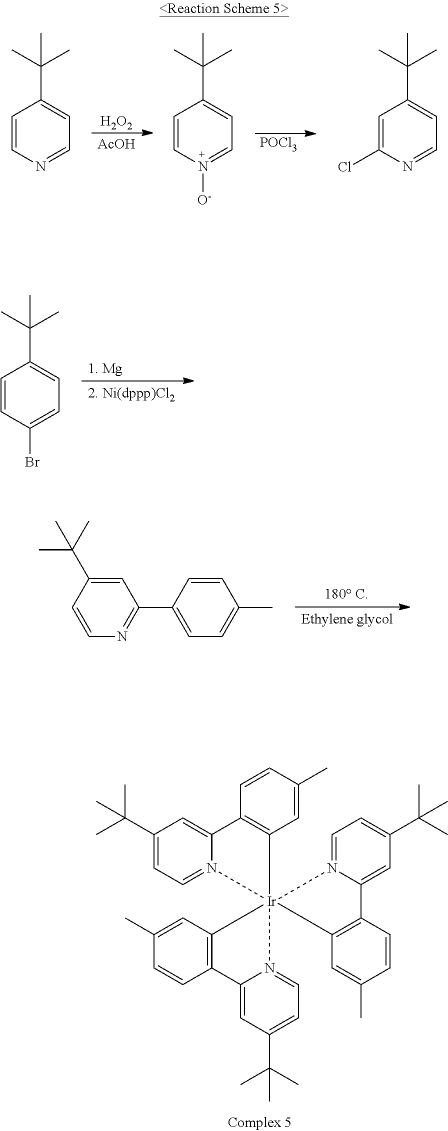

### Synthesis of 4-(tert-butyl)pyridine N-oxide

After adding 50 g (3.37 mmol) of 4-(tert-butyl)pyridine and 240 mL of acetic acid to a 500 mL 3-necked round bottom flask, 50.3 mL (0.44 mol) of 30% hydrogen peroxide was added thereto, and the resulting mixture was then heated under reflux overnight in a nitrogen atmosphere. The solvent was removed from the resulting reaction mixture, and the temperature was cooled to room temperature. The product concentrates were then neutralized with NaOH solution and extracted with dichloromethane. After removing moisture from the resulting reaction mixture using anhydrous MgSO₄, the solvent was removed to obtain 52 g (Yield: 95%) of 4-(tert-butyl)pyridine N-oxide.

### Synthesis of 4-(tert-butyl)-2-chloropyridine

After adding 150 mL (1.59 mol) of POCl₃ to a 500 mL (1.59 mol) 3-necked round bottom flask, 40 g (0.26 mol) of 4-(tert-butyl)pyridine N-oxide was added thereto, and the resulting mixture was then heated under reflux overnight in a nitrogen atmosphere. After completion of the reaction, POCl₃ was removed and neutralized, and then extracted with chloroform. After removing the moisture from the resulting reaction mixture using anhydrous MgSO₄, the solvent was removed. The resulting product was purified by distillation to obtain 21.5 g (Yield: 48%) of 4-(tert-butyl)-2-chloropyridine.

¹H-NMR (300 MHz, CD2Cl2, δ ppm): 8.13 (d, 1H), 7.15 (s, 1H), 7.08 (d, 1H), 1.15 (s, 9H)

### Synthesis of 4-tert-butyl-2-p-tolylpyridine

After adding 1.86 g (76.63 mmol) of Mg and 50 mL of diethyl ether to a 100 mL 3-necked round bottom flask in a nitrogen atmosphere, 13.10 g (76.63 mmol) of 1-bromo-4-methylbenzene was added thereto, and the resulting mixture was then stirred for about 3 hours to obtain the corresponding Grignard reagent. After adding 10 g (58. 94 mmol) of 4-(tert-butyl)-2-chloropyridine and 0.32 g (0.59 mmol) of Ni(dppp)Cl₂ to 50 mL of diethyl ether contained in a 250mL 3-necked flask, then stirring, the Grignard reagent was dropwise added thereto, and the resulting reaction mixture was allowed to react overnight. After quenching the reaction by adding water thereto, the resulting reaction mixture was extracted with ethyl acetate. After removing the moisture from the the ethyl acetate extracts using anhydrous MgSO₄, the solvent was removed. The resulting crude reaction product mixture was purified using column chromatography to obtain 7.5 g (Yield: 56%) of 4-tert-butyl-2-p-tolylpyridine.

¹H-NMR (300 MHz, CD2Cl2, δ ppm): 8.61 (d, 1H), 7.91 (d, 2H), 7.71(s, 1H), 7.32 (d, 2H), 7.24(d, 1H), 2.43(s, 3H), 1.38 (s, 9H)

Synthesis of Complex 5

After adding 1 g (4.44 mmol) of 4-tert-butyl-2-p-tolylpyridine and 0.54 g (1.11 mmol) of iridium acetylacetonate to a 50 mL 3-necked round bottom flask, 20 mL of ethylene glycol was added thereto. After degassing, the resulting reaction mixture was stirred at 180° C. for 24 hours, and the temperature was then cooled to room temperature. After adding water to and stifling the resulting reaction product mixture, the resulting reaction product mixture was filtered with a filter, and the crude filtered product was washed with EtOH, then purified using column chromatography to obtain 0.43 g (Yield: 46%) of Complex 5.

¹H-NMR (300 MHz, CD2Cl2, δ ppm): 7.89 (s, 3H), 7.63 (d, 3H), 7.38 (d, 3H), 6.94 (m, 3H), 6.75 (d, 3H), 6.66 (s, 3H), 2.14 (s, 9H), 1.37 (s, 27H)

### EVALUATION EXAMPLE 1

### Evaluation of Light Emission Characteristics of Complexes 1 to 5

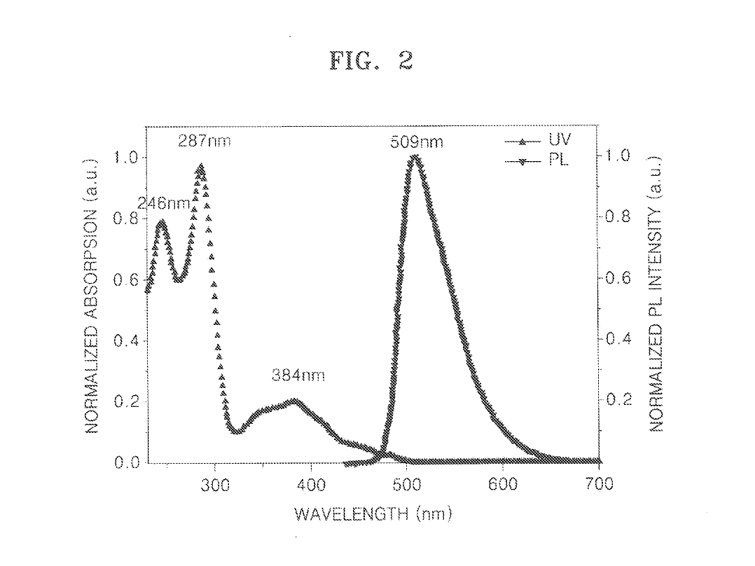

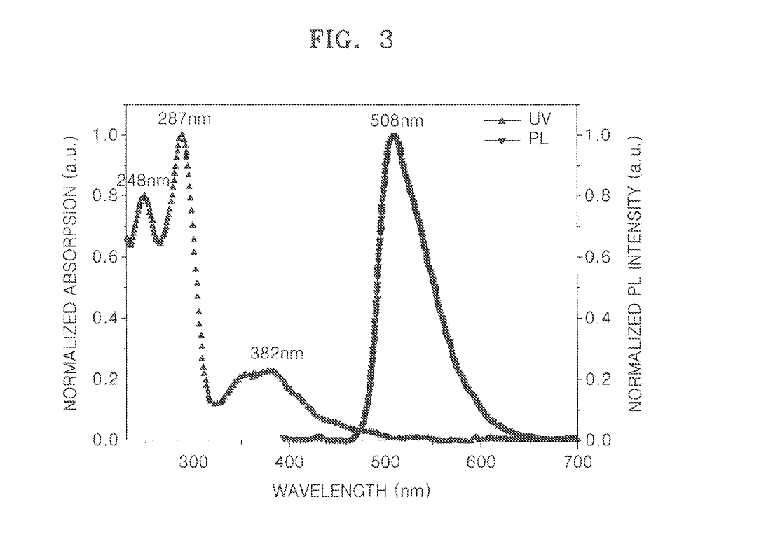

UV absorption spectra and photoluminescence (PL) spectra of Complexes 1 to 5, which were synthesized in Synthesis Examples 1 to 5, were analyzed to evaluate the light emission characteristics of Complexes 1 to 5. Complex 1 was diluted to a concentration of 0.2 mM in toluene, followed by measuring UV spectrum of Complex 1 using a Shimadzu UV-350 Spectrometer. UV absorption spectra of Complexes 2 to 5 and Ir(ppy)₃ were measured in the same manner as for Complex 1. Complex 1 was diluted to a concentration of 10 mM in toluene, followed by measurement of the PL spectrum of Complex 1 using an ISC PC1 Spectrofluorometer equipped with a xenon lamp. PL spectra of Complexes 2 to 5 and Ir(ppy)₃ were measured in the same manner as for Complex 1. The results of the measurements are shown in Table 1 below. UV absorption spectra and PL spectra of Complexes 1 and 2 are shown in FIGS. 2 and 3, respectively.

TABLE 1

| | Peak's | PL peak | HWHM at the | |
|---|---|---|---|---|
| | wavelength in | wavelength | peak of PL | |
| | UV absorption | max | spectrum | PL color |
| | spectrus (nm) | (nm) | (nm) | coordinates |
| Complex | 246, 287, 384 | 509 | 60.3 | (0.244, 0.631) |
| 1 | | | | |
| Complex | 248, 287, 382 | 508 | 60.4 | (0.245, 0.608) |
| 2 | | | | |
| Complex | 247, 287, 385 | 510 | 61.2 | (0.230, 0.650) |
| 3 | | | | |
| Complex | 247, 289, 384 | 517 | 63.2 | (0.275, 0.643) |
| 4 | | | | |
| Complex | 246, 287, 375 | 508 | 60.6 | (0.240, 0.623) |
| 5 | | | | |
| Ir(ppy)₃ | 244, 283, 380 | 513 | 64.9 | (0.266, 0.633) |

<Ir(ppy)₃>

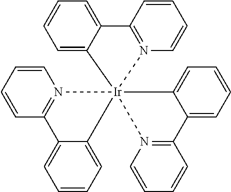

Based on Table 1, FIG. 2, and FIG. 3, emission peaks of Complexes 1 to 5 have smaller HFWH than emission peak of Ir(ppy)₃, which means that green light with excellent color purity may be emitted.

### EVALUATION EXAMPLE 2

### Evaluation on Thermal Stabilities of Complexes 1, 2, 3 and 5

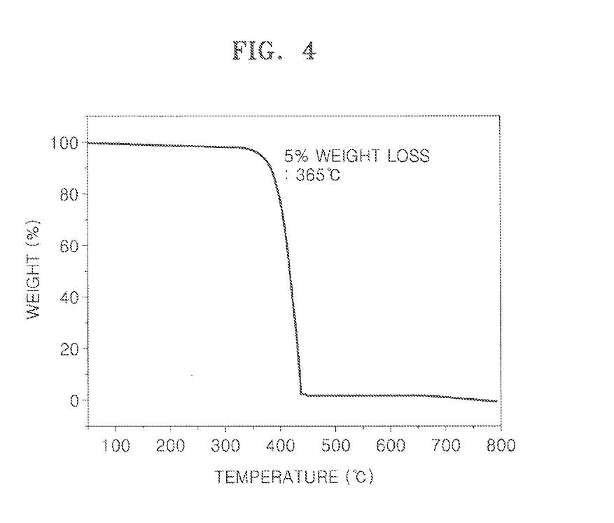

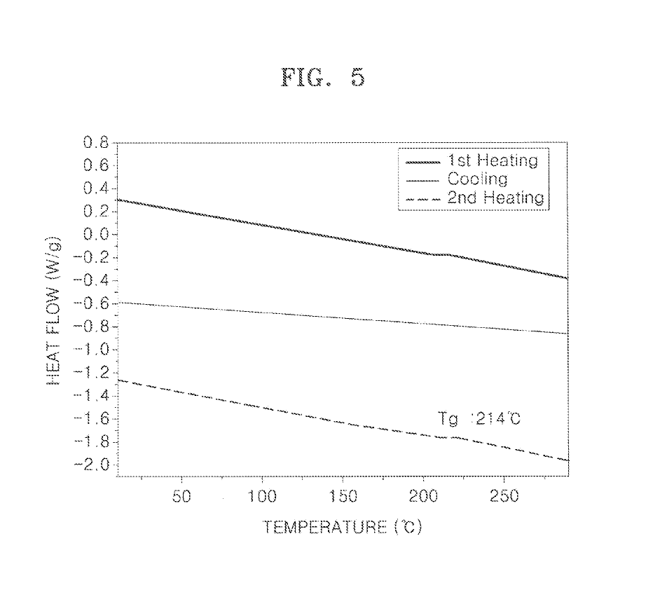

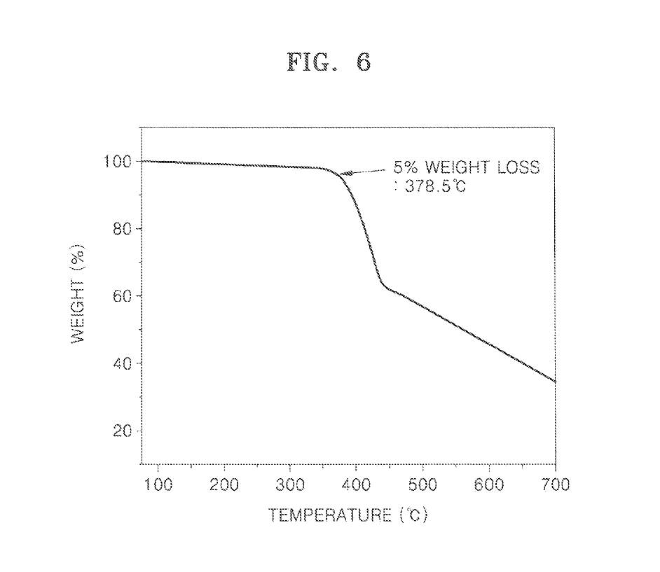

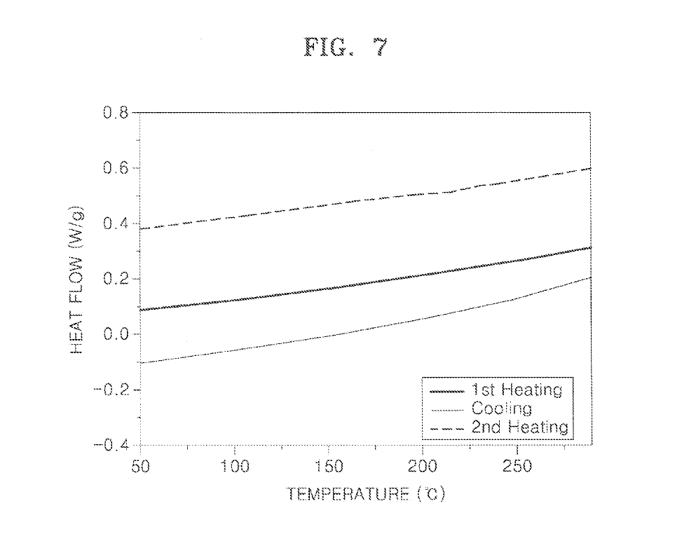

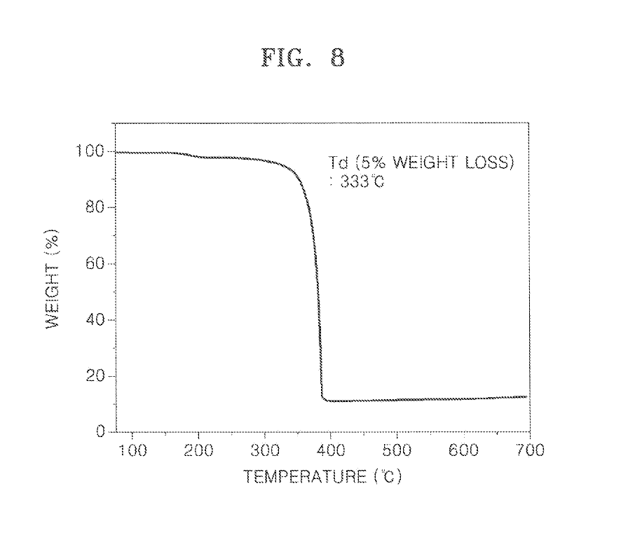

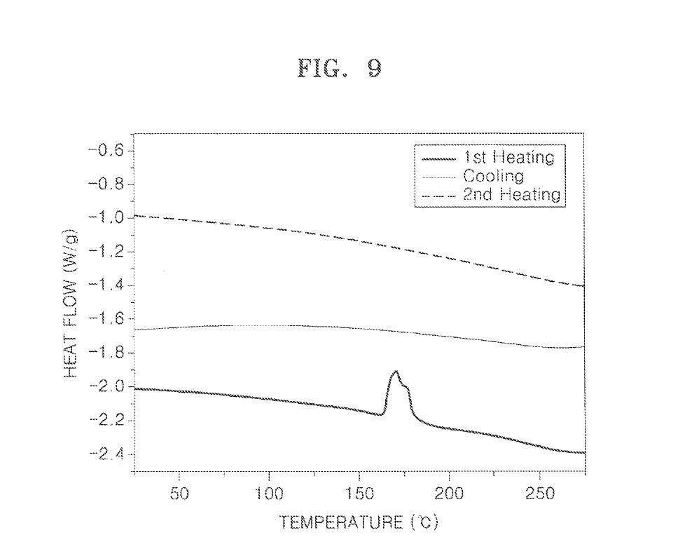

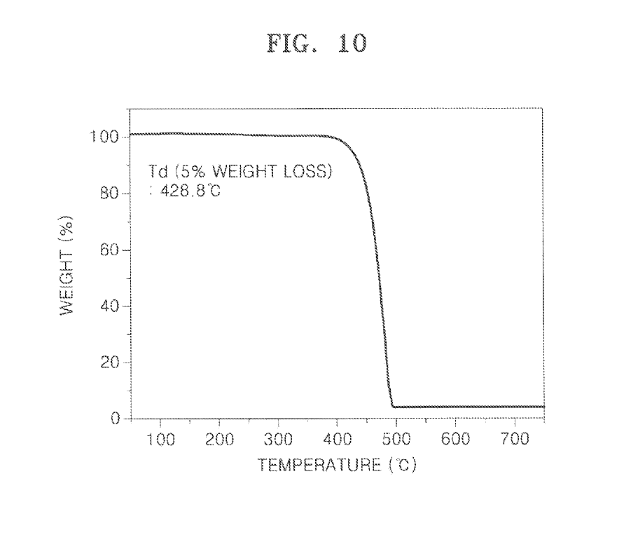

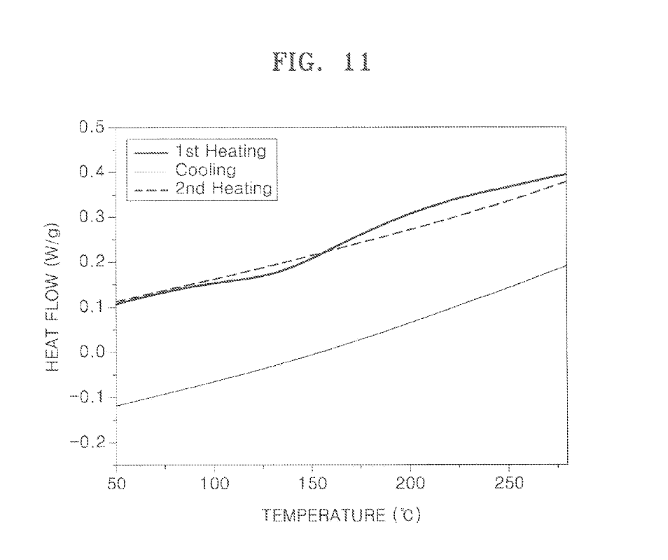

Thermal stabilities of Complexes 1, 2, 3 and 5 were evaluated by measuring glass transition temperature (Tg) and melting (Tm) of each Complex. Tg and Tm were measured by heat analysis (N₂ atmosphere, temperature range: from room temperature to 600° C. (10° C./min)-TGA, from room temperature to 400° C.-DSC, Pan Type: Pt Pan in disposable Al Pan (TGA), disposable Al pan(DSC) using Thermo Gravimetric Analysis (TGA) and Differential Scanning calorimetry (DSC). TGA data of Complex 1 are shown in FIG. 4, and DSC data of Complex 1 are shown in FIG. 5. In addition, TGA data of Complex 2 are shown in FIG. 6, and DSC data of Complex 2 are shown in FIG. 7. TGA data of Complex 3 are shown in FIG. 8, and DSC data of Complex 3 are shown in FIG. 9. In addition, TGA data of Complex 5 are shown in FIG. 10, and DSC data of Complex 5 are shown in FIG. 11. Tg and Tm of Complexes 1 and 2 are shown in Table 2 below.

TABLE 2

| Complex No . | Tg (° C.) | Tm (° C.) |
|---|---|---|
| 1 | 214 | — |
| 2 | none | — |

### EVALUATION EXAMPLE 3

### Evaluation on Electrical Abilities of Complexes 1, 2, 3 and 5

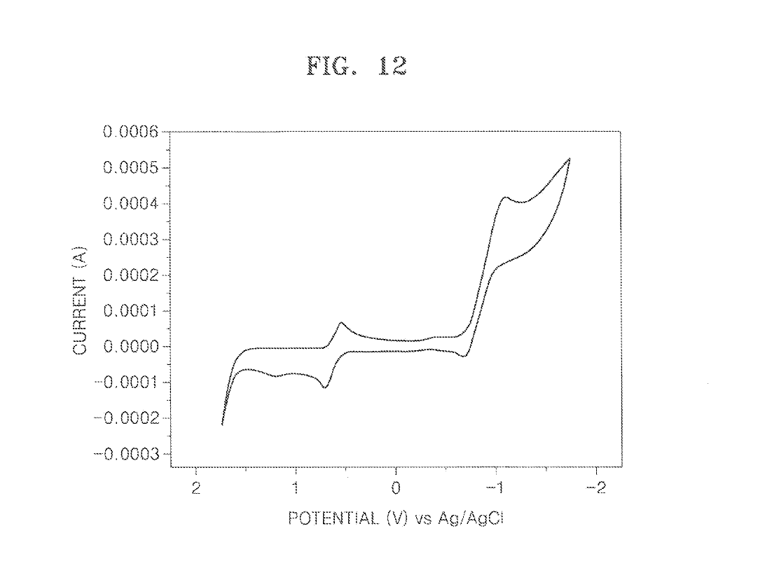

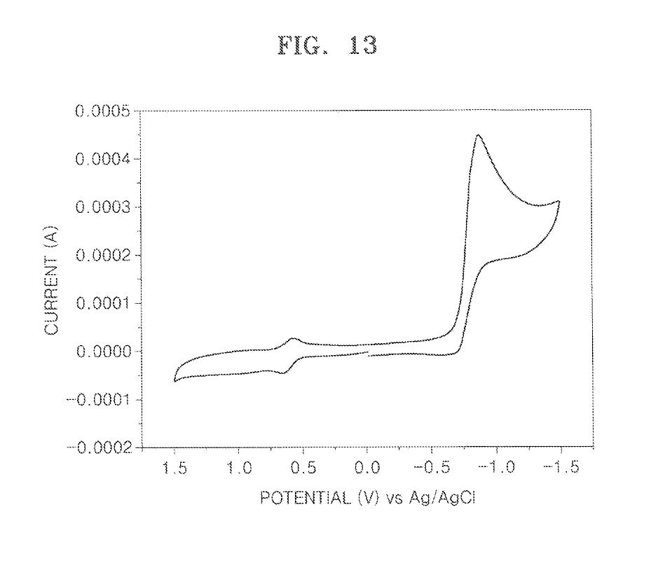

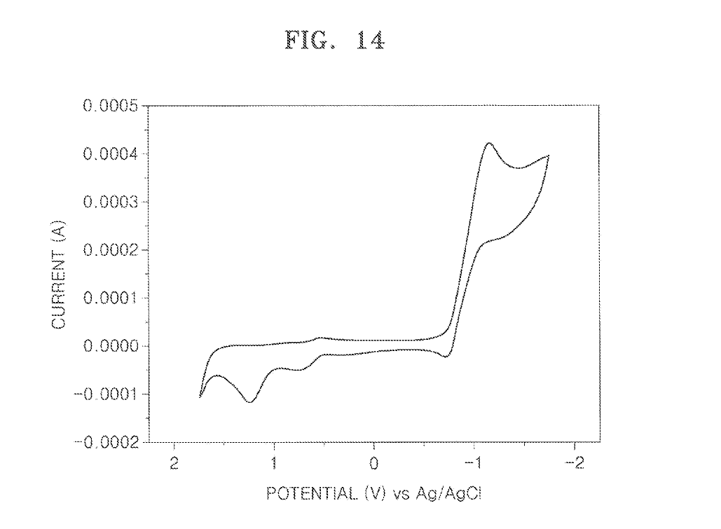

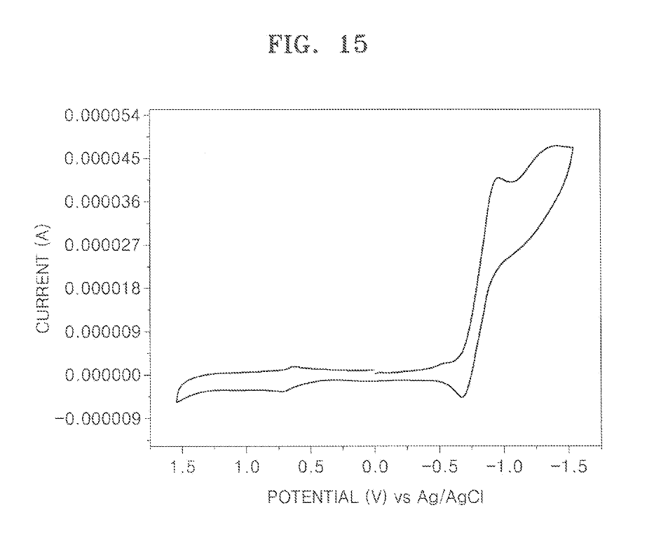

Electrical abilities of Complexes 1, 2, 3 and 5 were evaluated by Cyclic voltammetry (CV) (electrolyte: 0.1 M Bu₄NClO₄/solvent: CH₂Cl₂/electrode: a third electrode system (working electrode: GC, reference electrode: Ag/AgCl, auxiliary electrode: Pt)), and the results of electrical abilities are shown in FIGS. 12 to 15, respectively.

Referring to FIGS. 12 to 15, Complexes 1, 2, 3 and 5 were found to be suitable for use as OLED-compounds with appropriate electrical abilities.

### EXAMPLE 1

As an anode, 15 Ω/cm² (1200 Å ) ITO glass substrate of Corning was cut into size of 50 mm×50 mm×0.7 mm, followed by ultrasonic cleaning each for about 5 minutes using isopropyl alcohol and pure water. Following UV irradiation for about 30 minutes and exposure to ozone for cleaning, the glass substrate was loaded into a vacuum deposition device.

After 4.4′-bis[N-(1-naphthyl)-N-phenylamino]biphenyl (NPB) was deposited on top of the ITO layer to form a HIL having a thickness of about 400 Å, TCTA was deposited on top of the HIL to form a HTL having a thickness of about 100 Å.

Next, CBP (host) and Complex 2 (dopant) were co-deposited in a weight ratio of 97:3 to form an EML having a thickness about 300 Å.

Then, Bphen was deposited on top of the EML to form an ETL having a thickness of about 500 Å, and LiF was deposited on top of the EML to form an EIL having a thickness of about 10 Å, and AI was deposited on top of the EIL to form a second electrode (cathode) having a thickness of about 1100 Å to manufacture an OLED.

### EXAMPLE 2

An OLED was manufactured in the same manner as in Example 1, except that a weight ratio of CBP: Complex 2 was changed to 96:4, was used to form the EML.

### EXAMPLE 3

An OLED was manufactured in the same manner as in Example 1, except that a weight ratio of CBP: Complex 2 was changed to 95:5, was used to form the EML.

### EXAMPLE 4

An OLED was manufactured in the same manner as in Example 1, except that a weight ratio of CBP: Complex 2 was changed to 94:6, was used to form the EML.

### EXAMPLE 5

An OLED was manufactured in the same manner as in Example 1, except that a weight ratio of CBP: Complex 2 was changed to 92:8, and this mixture was used to form the EML.

### EXAMPLE 6

An OLED was manufactured in the same manner as in Example 1, except that Complex 3 was used instead of Complex 2.

### EXAMPLE 7

An OLED was manufactured in the same manner as in Example 1, except that Complex 5 was used instead of Complex 2.

### EVALUATION EXAMPLE 4

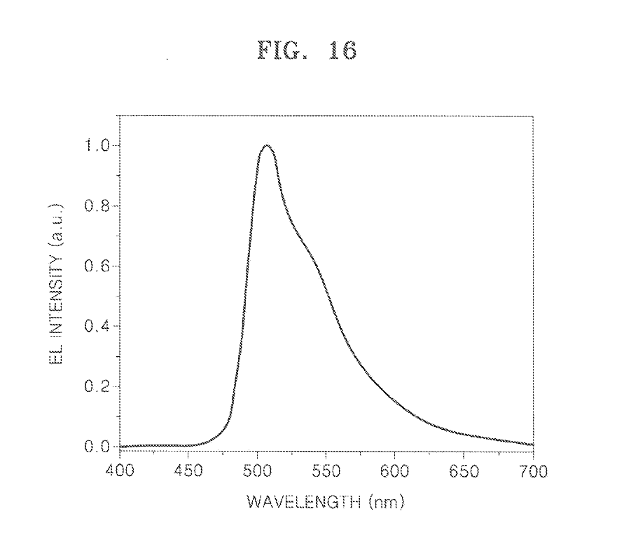

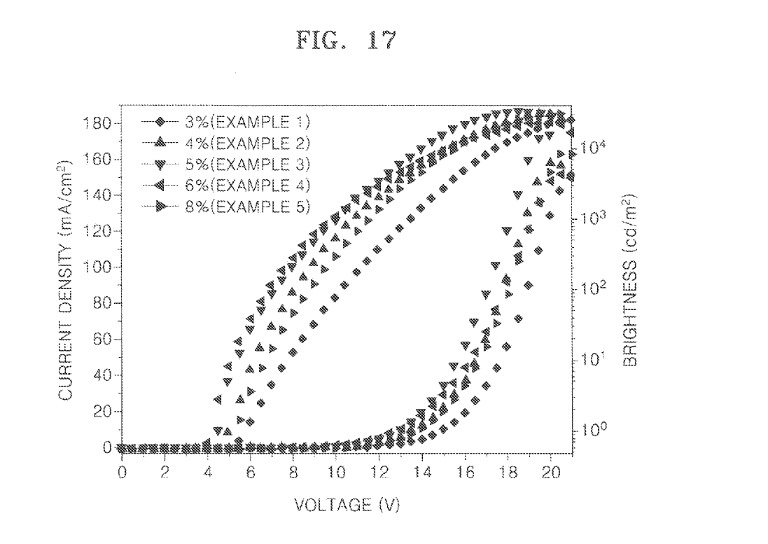

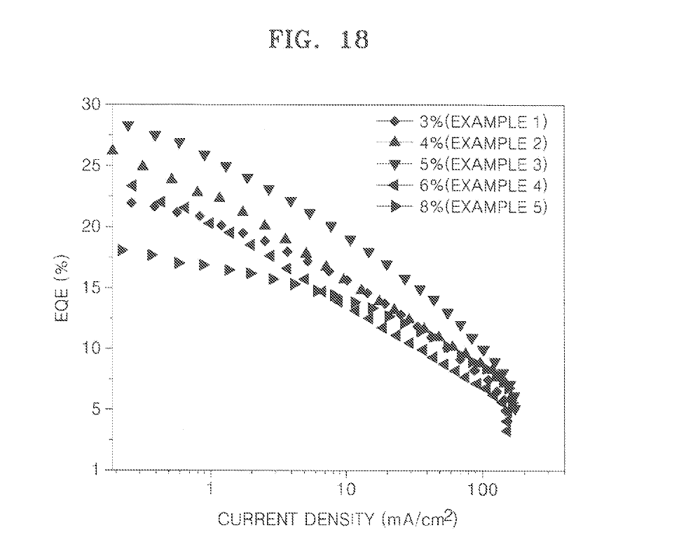

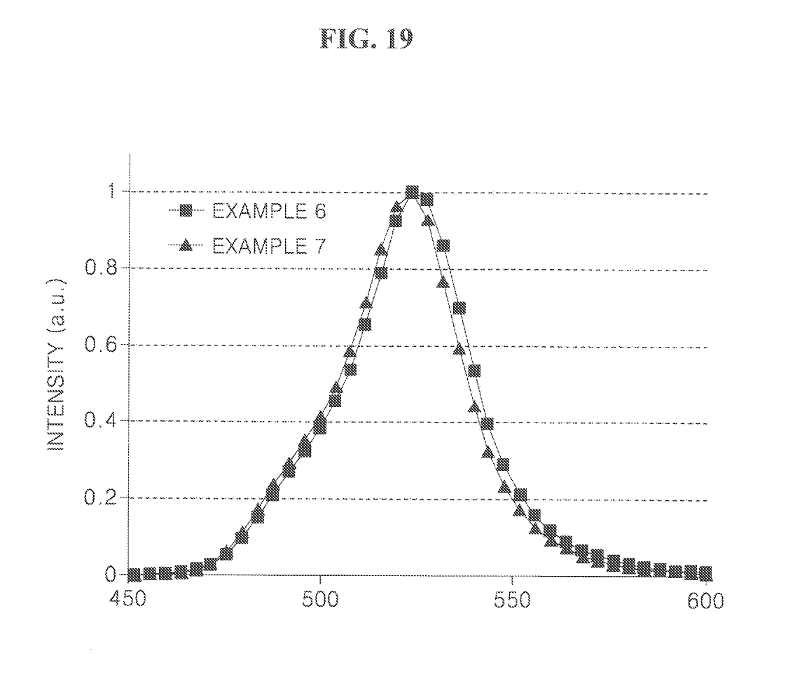

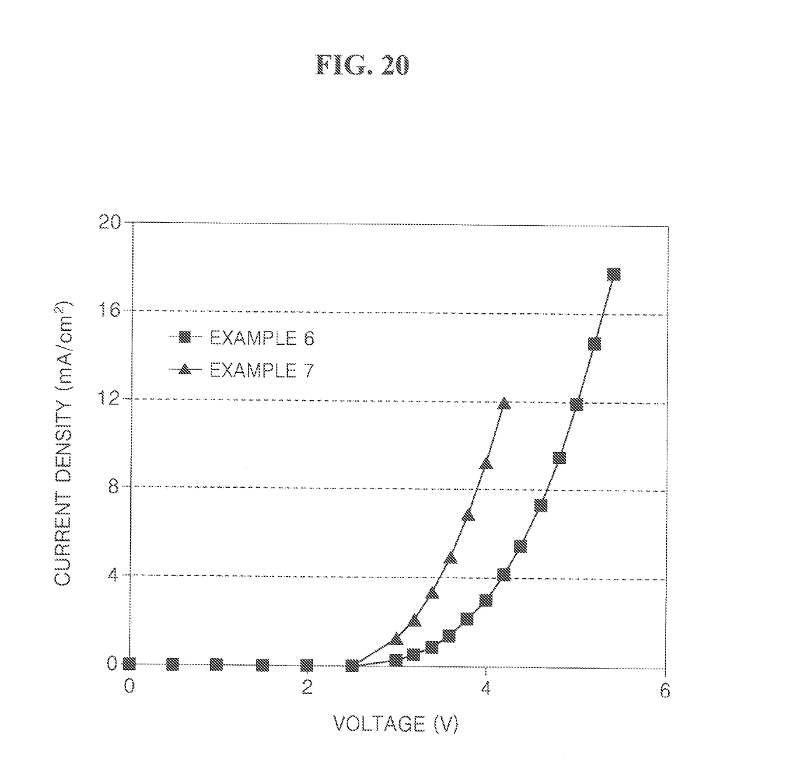

Driving voltages, brightness, external quantum efficiencies, electric powers, electric power efficiencies, maximum wavelengths of EL spectrum, and color purities of each OLED from Examples 1 to 7 were evaluated using PR650 Spectroscan Source Measurement Unit (PhotoResearch, Inc.). The results are shown in the Tables 3 to 5 below. An electroluminescent (EL) spectrum of an organic light-emitting device prepared according to Example 1 is shown in FIG. 16, voltage-current density and voltage-brightness plots of organic light-emitting devices prepared according to Examples from 1 to 5 are shown in FIG. 17, voltage-current density-quantum efficiency (EQE) plots of organic light-emitting devices prepared according to Examples from 1 to 5 are shown in FIG. 18, electroluminescent (EL) spectra of organic light-emitting devices prepared according to Examples 6 and 7 are shown in FIG. 19 and voltage-current density plots of organic light-emitting devices prepared according to Examples 6 and 7 are shown in FIG. 20.

TABLE 3

| | Dopant | Driving | | | | | | | External | |
|---|---|---|---|---|---|---|---|---|---|---|
| | (Concentration | voltage | brightness | | brightness | | brightness | | quantum | |
| | of | (V) at | (cd/m²) | | (cd/m²) | | (cd/m²) | | yield (%) | |
| | dopant) | 1 cd/m² | (V) | | (V) | | (max, V) | | (V) | |
| Example 1 | Complex 2 | 5.5 | 77.25 | (10) | 1024 | (113.5) | 24470 | (21) | 21.93 | (11) |
| | (3 wt %) | | | | | | | | | |
| Example 2 | Complex 2 | 5 | 89.5 | (8) | 1102 | (11) | 30.920 | (20) | 26.30 | (8.5) |
| | (4 wt %) | | | | | | | | | |
| Example 3 | Complex 2 | 4.5 | 85.56 | (7) | 977.5 | (10) | 33560 | (19) | 28.32 | (8) |
| | (5 wt %) | | | | | | | | | |
| Example 4 | Complex 2 | 4.5 | 115.3 | (7) | 1092 | (10) | 23340 | (20) | 23.43 | (7.5) |
| | (6 wt %) | | | | | | | | | |
| Example 5 | Complex 2 | 5.5 | 75.32 | (8.5) | 950 | (11.5) | 30800 | (20) | 18.12 | (9) |
| | (8 wt %) | | | | | | | | | |

TABLE 4

| | Dopant | Effi- | Electric | | |
|---|---|---|---|---|---|
| | (Concen- | ciency | power | Maximum | Color purity |
| | tration | (cd/A) | (Lm/W) | wavelength | at CE max |
| | of dopant) | (V) | (V) | of EL (nm) | EL max |
| Example 1 | Complex 2 | 64.72 | 18.48 | 508 | (0.26, 0.61) |
| | (3 wt %) | (11) | (11) | | (0.27, 0.61) |
| Example 2 | Complex 2 | 77.79 | 28.75 | 508 | (0.26, 0.61) |
| | (4 wt %) | (8.5) | (8.5) | | (0.27, 0.61) |
| Example 3 | Complex 2 | 84.30 | 33.10 | 508 | (0.26, 0.61) |
| | (5 wt %) | (8) | (8) | | (0.27, 0.61) |
| Example 4 | Complex 2 | 69.29 | 29.02 | 508 | (0.26, 0.61) |
| | (6 wt %) | (7.5) | (7.5) | | (0.27, 0.61) |
| Example 5 | Complex 2 | 53.92 | 18.82 | 508 | (0.27, 0.61) |
| | (8 wt %) | (9) | (9) | | (0.27, 0.61) |

TABLE 5

| | Dopant | | | | | |
|---|---|---|---|---|---|---|
| | (Con- | Driving | Current | | | |
| | centration | voltage | density | bright- | | |
| | of | (V) at | (mA/ | ness | | |
| | dopant) | 1 cd/m² | cm²) | (cd/A) | CIE_x | CIE_y |
| Example 6 | Complex 3 | 5.3 | 15.8 | 57.2 | 0.262 | 0.697 |
| | (3 wt %) | | | | | |
| Example 7 | Complex 5 | 4.0 | 9.5 | 95.2 | 0.246 | 0.706 |
| | (3 wt %) | | | | | |

Referring to Tables 3 to 5, the OLED's from Examples 1 to 7 are found to be low driving voltage but improved in terms of efficiency and color purity.

As described above, according to the one or more embodiments of the present invention, an organic light-emitting device including the organic metallocomplex of Formula 1 above may exhibit desirable qualities, for example, high efficiency and high color purity.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An organometallic complex represented by Formula 1 below: 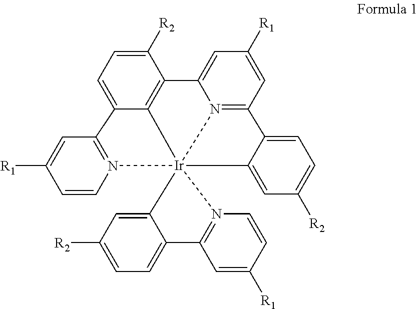
R₁ in Formula 1 is a hydrogen atom or a C₁-C₁₀ alkyl group; and
R₂ in Formula 1 is a Cᵢ-C₁₀ alkyl group.

2. The organometallic complex according to claim 1, R₁ and R₂ each being independently one of a methyl group, an ethyl group, a propyl group, an n-butyl group, an isobutyl group, a sec-butyl group, a tert-butyl group, an n-pentyl group, an isopentyl group, a sec-pentyl group, a tert-pentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonenyl group, an isononenyl group, a sec-nonenyl group, a tert-nonenyl group, an n-decanyl group, an isodecanyl group, a sec-decanyl group, and a tert-decanyl group.

3. The organometallic complex according to claim 1, R₁ and R₂ each being independently an ethyl group or a tert-butyl group.

4. The organometallic complex according to claim 1, the complex having a maximum emission wavelength in a range of from about 500 nm to about 530 nm.

5. The organometallic complex according to claim 1, the complex having a full width at half maximum in a range of from about 55 nm to about 62 nm.

6. The organometallic complex according to claim 1, being one of Complexes 1 to 5:

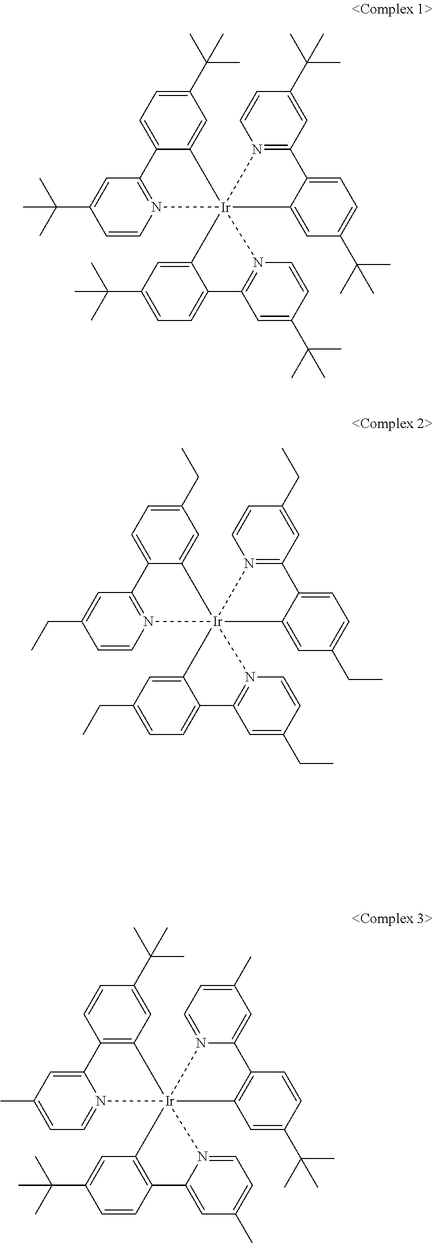

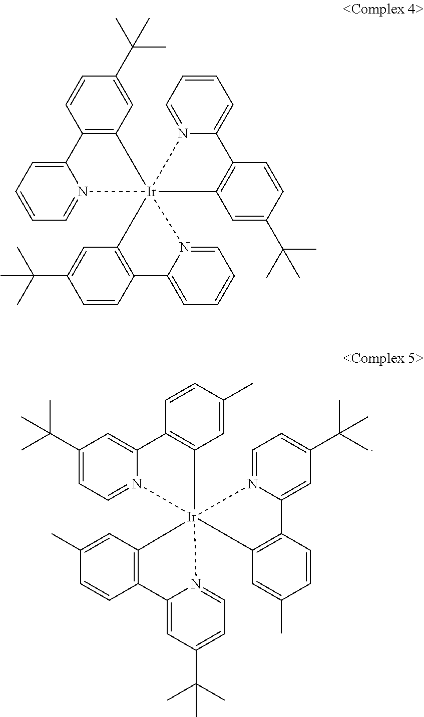

7. An organic light-emitting device comprising: a first electrode; a second electrode disposed opposite to the first electrode; and an organic layer disposed between the first electrode and the second electrode, the organic layer comprising at least one of the organometallic complexes of claim 1.

8. The organic light-emitting device of claim 7, the organic layer comprising at least one layer selected from among a hole injection layer, a hole transport layer, a functional layer having both hole injection and hole transport capabilities, a buffer layer, an electron blocking layer, an emission layer, a hole blocking layer, an electron transport layer, an electron injection layer, and a functional layer having both electron injection and electron transport capabilities.

9. The organic light-emitting device of claim 8, the organic layer comprising an emission layer, the organometallic complex being in the emission layer.

10. The organic light-emitting device of claim 9, the concentration of the organometallic complex being in a range of from about 1 wt % to about 30 wt % based on 100 wt % of the emission layer.

11. The organic light-emitting device of claim 9, the organometallic complex comprised in the emission layer serving as a phosphorescent dopant, the emission layer further comprising a carbazole-based host represented by Formula 100, 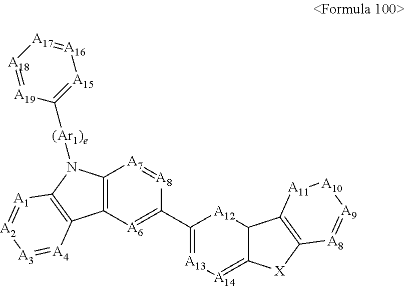
A₁ to A₁₉ being each independently CR₄₁ or N;
X being —C(R₄₂R₄₃)—, —N(R₄₄)—, —S—, —O—, —Si(R₄₅)(R₄₆)—, —P(R₄₇)—, —P(═O)(R₄₈)—, or —B(R₄₉)—;
Ar₁ being one of a substituted or unsubstituted C₆-C₆₀ arylene group and a substituted or unsubstituted C₂-C₆₀ heteroarylene group, Ar₁ being excluded if e=0 and A₁₅ to A₁₉ are all CR₄₁; R₄₁ to R₄₉ being each independently one of a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₂-C₆₀ heteroaryl group, —N(Q₁)(Q₂), —Si(Q₃)(Q₄)(Q₅), and —C(═O)(Q₆) (Q₁ to Q₆ being each independently one of a hydrogen atom, a substituted or unsubstituted C₁-C₆₀ alkyl group, a substituted or unsubstituted C₆-C₆₀ aryl group, and a substituted or unsubstituted C₂-C₆₀ heteroaryl group), at least two of R₄₁ to R₄₉ being optionally bound each other to form a saturated or unsaturated ring; and
e is an integer from 0 to 2.

12. The organic light-emitting device according to claim 9, the organometallic complex in the emission layer serving as a phosphorescent dopant, the emission layer further comprising a carbazole-based host represented by one of Formulas below:

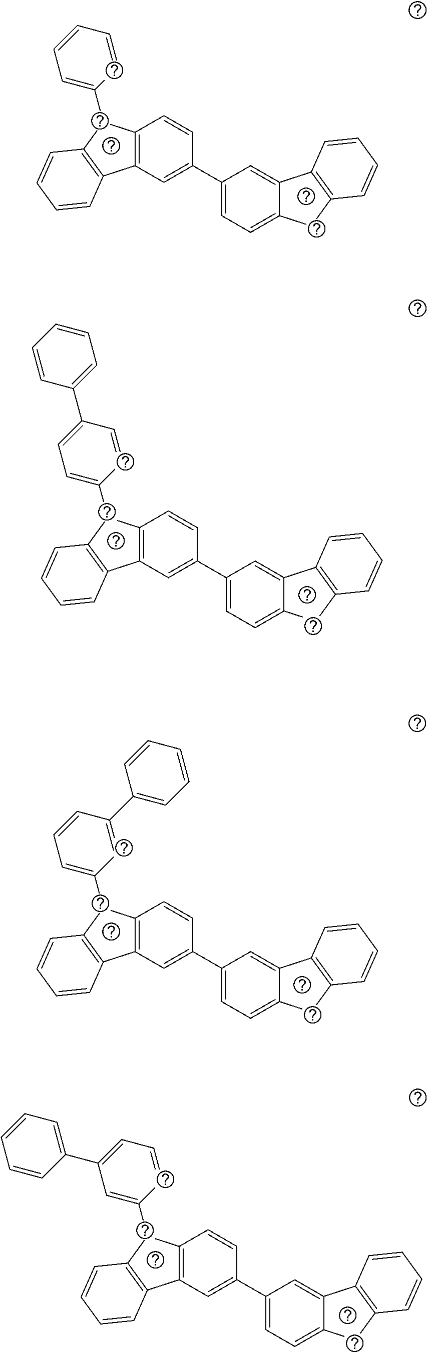

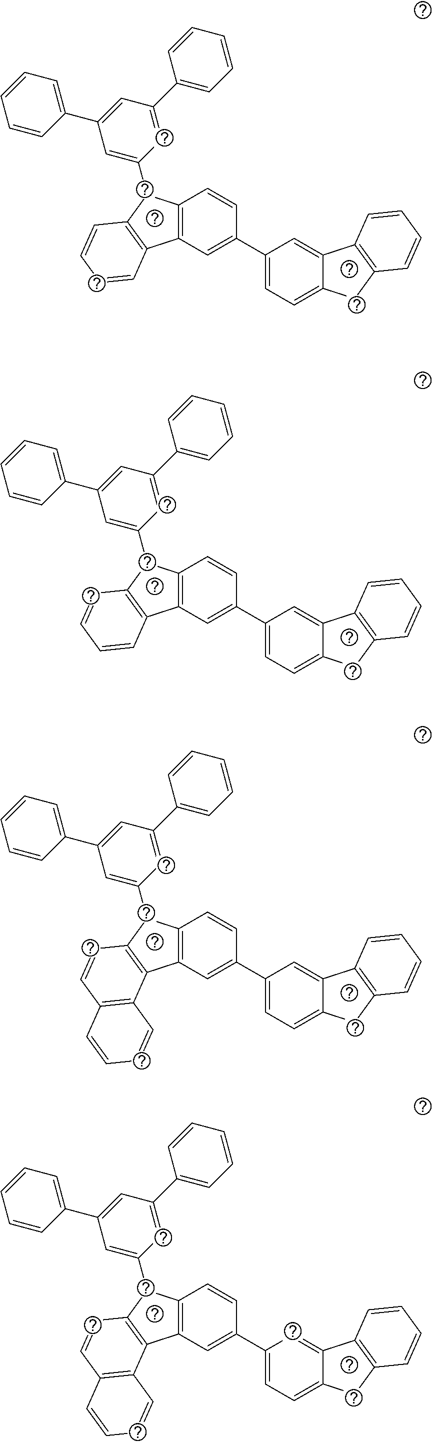

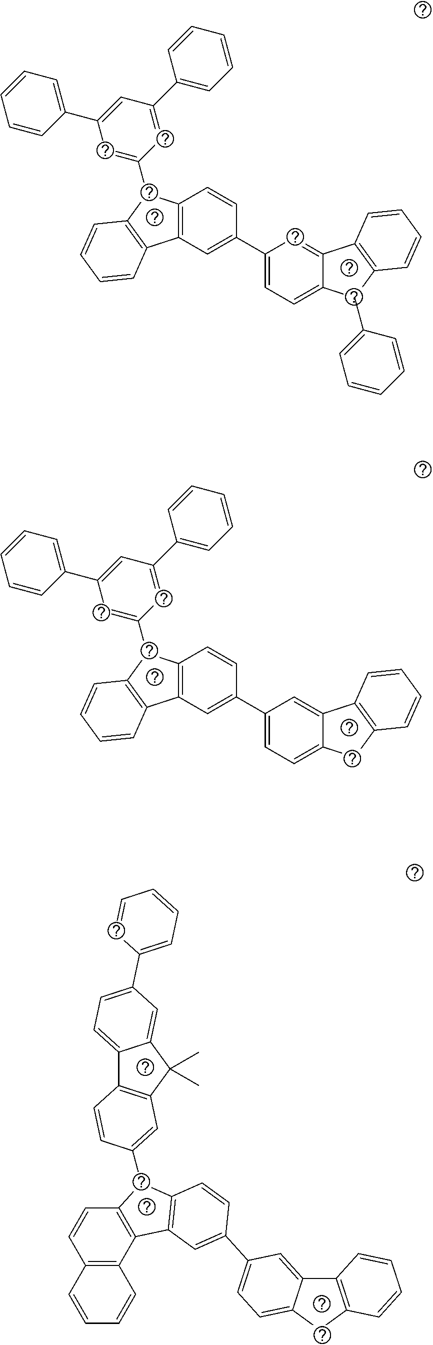

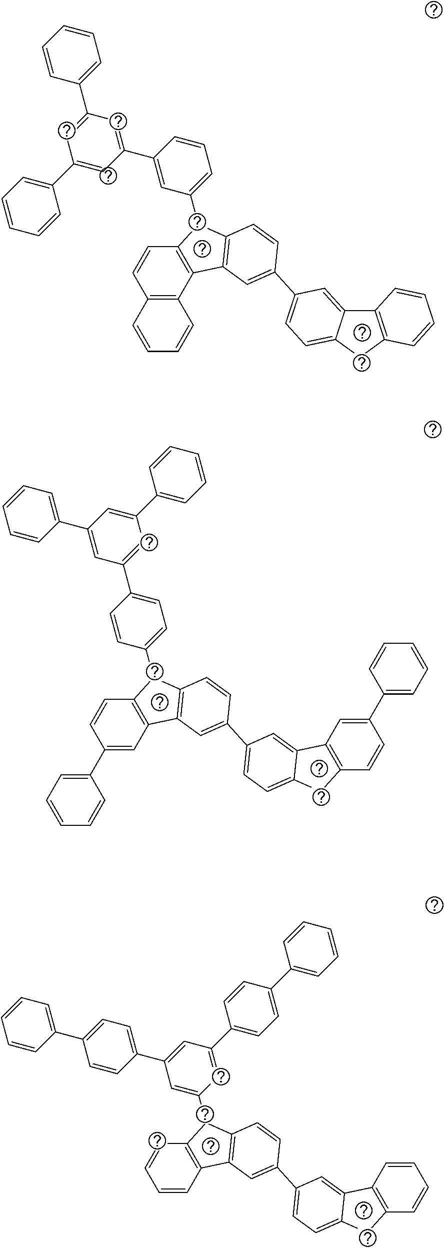

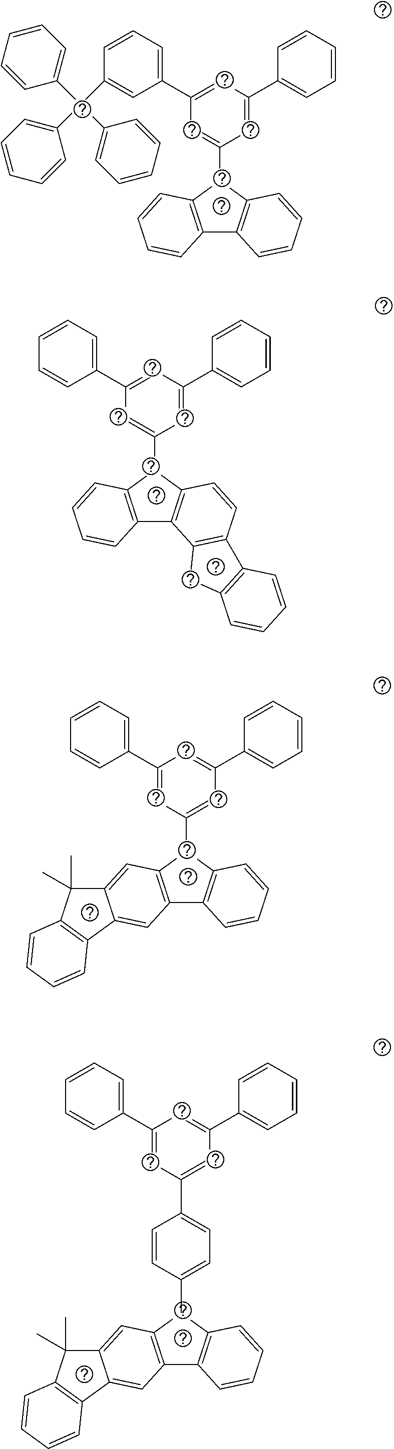

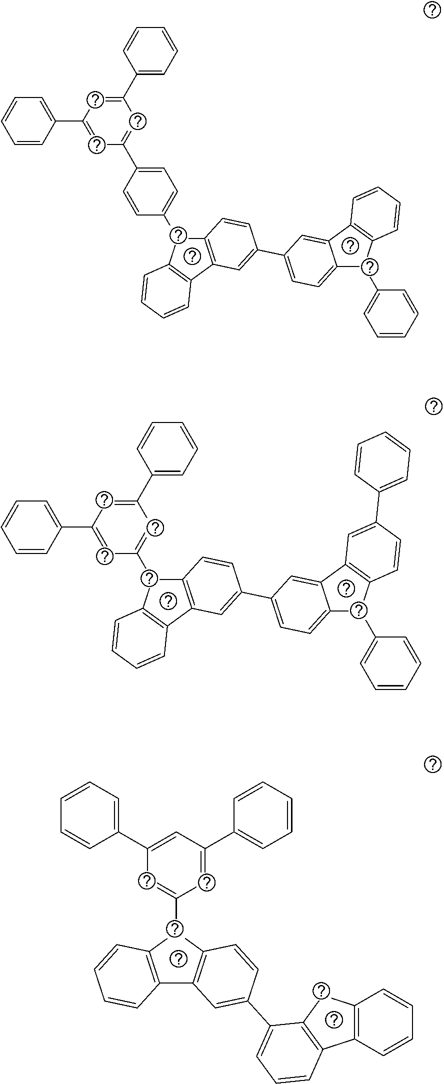

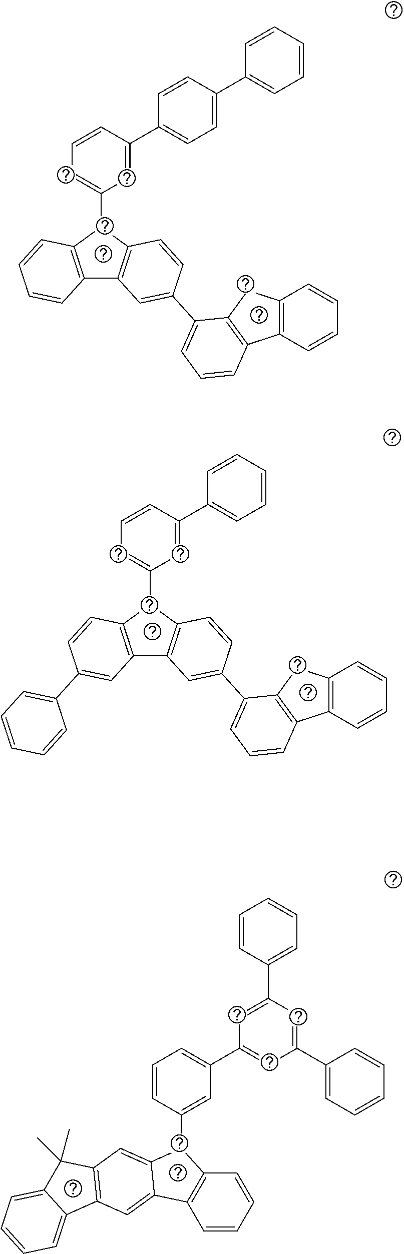

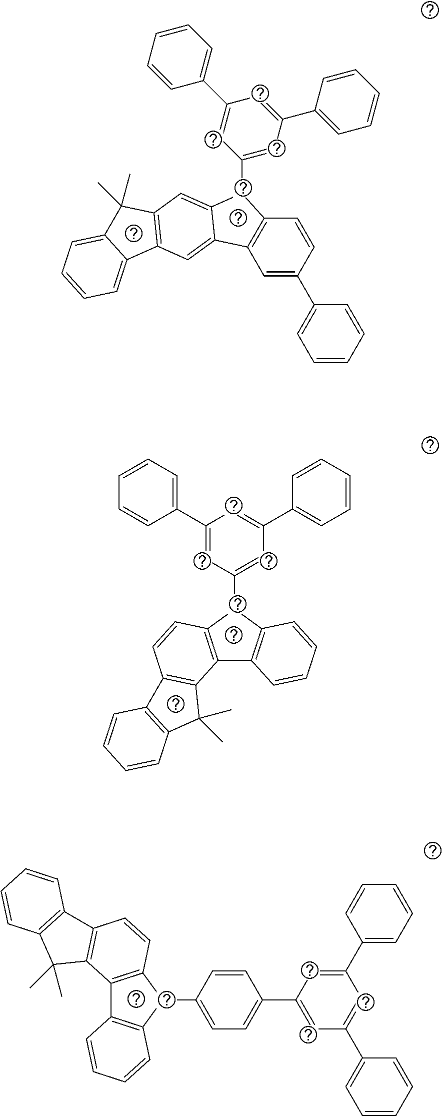

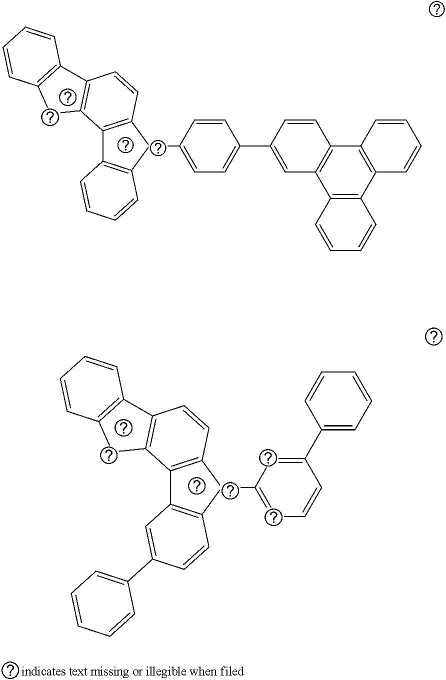

13. The organic light-emitting device according to claim 9, the emission layer emitting green phosphorescent light.

14. The organic light-emitting device according to claim 8, the organic layer comprising an electron transport layer, the electron transport layer further comprising a metal-containing material.

15. The organic light-emitting device according to claim 11, the metal-containing material comprising lithium quinolate.
